(19) United States
(12) Patent Application Publication
(10) Pub. No.: US 2009/0194810 A1
(43) Pub. Date: Aug. 6, 2009

(54) SEMICONDUCTOR DEVICE USING ELEMENT ISOLATION REGION OF TRENCH ISOLATION STRUCTURE AND MANUFACTURING METHOD THEREOF

(76) Inventors: Masahiro KIYOTOSHI, Yokkaichi-shi (JP); Hiroshi Kubota, Yokkaichi-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/361,340

(22) Filed: Jan. 28, 2009

(30) Foreign Application Priority Data
Jan. 31, 2008 (JP) 2008-021892
Jan. 31, 2008 (JP) 2008-021999
Aug. 5, 2008 (JP) 2008-201871

(51) Int. Cl. H01L 29/792; H01L 21/762; H01L 29/06

(52) U.S. Cl. 257/326; 438/435; 257/510; 257/E21.546; 257/E29.02; 257/E29.309

(57) ABSTRACT

A stacked film including a gate dielectric film and electrode film of each memory cell of a flash memory is formed on a semiconductor substrate. The stacked film is patterned by reactive ion etching to form an isolation trench for formation of an element isolation region and the surface of the semiconductor substrate is exposed to the internal portion of the isolation trench. An O₃-TEOS film exhibiting underlying material selectivity during the deposition is formed in the isolation trench as the first filling dielectric film and then the isolation trench is filled with the second filling dielectric film to form an element isolation region of an STI structure.

### CROSS-REFERENCE TO RELATED APPLICATIONS

This application is based upon and claims the benefit of priority from prior Japanese Patent Applications No. 2008-021892, filed Jan. 31, 2008; No. 2008-021999, filed Jan. 31, 2008; and No. 2008-201871, filed Aug. 5, 2008, the entire contents of all of which are incorporated herein by reference.

### BACKGROUND OF THE INVENTION

1. Field of the Invention

This invention relates to a semiconductor device using an element isolation region of a trench isolation structure and a manufacturing method thereof, which is applied to a flash memory and a flash memory manufacturing method, for example.

2. Description of the Related Art

Downsizing of LSIs is currently being advanced in order to enhance the performance of elements (enhance the operation speed and lower the power consumption) and suppress the manufacturing cost by increasing the elements density. Recently, logic devices whose gate width is less than 45 nm and flash memories whose half pitch is less than 50 nm are produced on a mass-production basis, which raises the technical difficulty. However, it is predicted that downsizing will be further advanced in the future.

In order to attain the rapid downsizing of elements, it is important to shrink an element isolation region that occupies a large part of the element area. As an element isolation region forming method, a shallow trench isolation (STI) technique for filling a dielectric film into a trench formed by anisotropic etching is used (for example, see Jpn. Pat. Appln. KOKAI Publication No. H11-297811). The element isolation region of the STI structure can be used to isolate elements in a narrower region in comparison with a case of a local-oxidation-of-silicon (LOCOS) structure, thus making it suitable for downsizing. The trench width of the element isolation region of the STI structure is not larger than 0.1 μm and, specifically, it is set to approximately 50 nm from 70 nm.

It therefore becomes more important to further shrink the element isolation region, but, at the same time, it rapidly becomes more difficult to form the element isolation region as the downsizing is further advanced. This is because isolation between the elements is determined based on the effective distance between the adjacent elements, that is, the shortest distance of a bypass around the element isolation region, thus it is necessary to keep the effective distance approximately equal to the distance used conventionally in order to prevent the insulating property from being lowered when the device is shrunk. That is, it is required to set the width of the STI trench narrow while maintaining a substantially constant depth. Therefore, the aspect ratio of an isolation trench in which a dielectric film is filled becomes higher for each generation of downsizing, thus rapidly increasing the difficulty in filling the dielectric film.

Particularly, since the aspect ratio is set to 3 or more in the generation after the generation of 0.1 μm, in a process performed for filling a silicon oxide film formed by a high density plasma-CVD (HDP-CVD) method and used, at present, as a standard technique for filling a dielectric film into an isolation trench, it becomes extremely difficult to perform the filling process without causing any voids (non-filled portions).

For example, as is disclosed in Japanese Patent Specification No. 3178412, it is proposed to use a spin-on-dielectric (SOD) film for filling. That is, an oxide film is filled and formed in a trench by spin-coating a solution such as a perhydropolysilazane solution and performing a heating process. However, it is necessary to make the element isolation trench deep in order to maintain the insulating characteristic of the element isolation region, thus and the volume of SOD material in the element isolation trench is increased as the trench is made deeper. Since the SOD film shrinks in the heating process, the tensile stress accordingly increases, and crystalline defects caused by dislocation tend to occur in the semiconductor substrate.

Further, in a logic device, the process of filling using an O₃-TEOS film having fluidity is being dominantly used. However, in the case of using an O₃-TEOS film, it is vital to perform a curing process by oxidation in the high-temperature steam atmosphere in order to eliminate voids or seams. Particularly, when the above method is applied to a flash memory in which a gate dielectric film is formed in advance, the following problem occurs.

First, since the effective film thickness of a gate dielectric film increases due to oxidation of the substrate and floating gate by diffusion of an oxidizing agent from the STI edge in the oxidation in the steam atmosphere process at the STI formation time and the reliability is lowered, it is difficult to apply the oxidation in the steam atmosphere process.

Further, an isolation trench is generally formed by reactive ion etching. Particularly, if the process is applied to a flash memory in which a gate dielectric film is formed in advance, the substrate and floating gate are oxidized by diffusion of an oxidizing agent from the STI edge, the film thickness is increased and the reliability is lowered at the time of oxidation of an active area (AA) for eliminating etching damage from the internal surface of the isolation trench.

Further, in a device in which the gate electrode is not formed in advance, AA becomes narrow due to oxidation during the STI formation process and a sufficient ON current cannot be attained.

In the flash memory, charges are injected into the floating gate electrode that is electrically insulated to store information. In the case of a NAND flash memory, since word lines of a cell portion are separated by gaps approximately equal to the minimum half pitch, it is important to suppress program disturb in which charges are injected into a non-selected floating gate adjacent to a selected floating gate when charges are injected into the selected floating gate.

However, the difficulty increases with downsizing. This is because the parasitic capacitance between adjacent word lines increases in inverse proportion to the distance between the adjacent word lines with downsizing. Further, the influence of parasitic capacitance between the adjacent word lines is raised by the process described below. That is, an LPCVD silicon oxide film that is generally excellent in step coverage is filled in portions between the adjacent word lines (WL) and when the LPCVD silicon oxide film is filled, a seam that is a film-formation joint is present in the central portion of a groove between WLs. Therefore, etchant penetrates into the seam portion and the central portion of the silicon oxide film between WLs is etched in a groove form when the surface of a polysilicon film used as a control gate electrode is exposed and dry etching or wet etching of a metal sputtering pre-process for silicidation is performed.

Next, a control gate electrode is patterned by subjecting polysilicon of the word line to silicidation and a silicon nitride film is deposited in a gap formed by etching the LPCVD silicon oxide film in the groove form when the surface of the control gate electrode is covered with the silicon nitride film to protect the same at the ILD formation time.

Since the dielectric constant of the silicon nitride film is as large as 1.7 times that of the silicon oxide film, there occurs a problem that the parasitic capacitance between adjacent word lines increases. The influence given by the parasitic capacitance between the word lines to the device characteristic is reported by, for example, Mr. Kang et al. (see IEDM “Improving the Cell Characteristics Using Low-K Gate Spacer in 1 Gb NAND Flash Memory”, 2006). Intrusion of the silicon nitride film can be neglected in a device in which the minimum processing size is not smaller than 100 nm but greatly affects the device operation in a device in which the minimum processing size is smaller than 60 nm.

This is because the width of extension of the seam portion in etching does not depend on the minimum processing size and the amount of the silicon nitride film entering a portion between the word lines cannot be neglected when comparing the device with the device of a generation of 100 nm or more. Further, the problem of the parasitic capacitance becomes serious due to downsizing because the distance between the adjacent word lines is reduced due to rapid downsizing of elements, the process of filling the dielectric film into portions between word lines becomes difficult and the parasitic capacitance becomes larger since the distance is reduced.

### BRIEF SUMMARY OF THE INVENTION

According to one aspect of this invention, there is provided a manufacturing method of a semiconductor device that includes forming a stacked film configuring a semiconductor device on a semiconductor substrate, processing the stacked film by reactive ion etching to form an isolation trench that isolates elements and expose a surface of the semiconductor substrate at least a bottom portion of the isolation trench, filling an O₃-TEOS series film exhibiting underlying material selectivity as a first filling dielectric film in the isolation trench to have a thicker film thickness on the bottom portion of the isolation trench, and filling the isolation trench with a second filling dielectric film to form an element-element insulating region.

According to another aspect of this invention, there is provided a semiconductor device that includes an active area formed on a semiconductor substrate, and a shallow trench isolation portion having an isolation trench formed to separate the active area from an adjacent active area and a dielectric film filled in the isolation trench, wherein the dielectric film filled in the isolation trench is a stacked film having a first dielectric film formed of an O₃-TEOS series film filled to have a thicker film thickness on a bottom portion of the isolation trench and the second dielectric film formed on the first dielectric film.

According to still another aspect of this invention, there is provided a semiconductor device that includes memory cells each having a gate dielectric film, charge storage layer, inter-polysilicon gate dielectric film and control gate stacked and formed on a semiconductor substrate, an element isolation region of a trench isolation structure formed on the semiconductor substrate, first dielectric films formed of O₃-TEOS series films filled in portions on an active area between adjacent word lines without causing any seam, second dielectric films filled on the first dielectric films in the portions between adjacent word lines, and third dielectric films filled to surround upper portions of the element isolation region in the portions between adjacent word lines.

### BRIEF DESCRIPTION OF THE SEVERAL VIEWS OF THE DRAWING

FIGS. 1 to 3 are cross-sectional views showing first to the third steps of a manufacturing process of a floating gate flash memory formed on a partial SOI substrate as an example, for illustrating the first embodiment of this invention;

FIG. 4 is a cross-sectional view showing one step of a manufacturing process of a flash memory corresponding to the cross-sectional view of the third step shown in FIG. 3 as an example, for illustrating a manufacturing method of a semiconductor device of a comparison example;

FIG. 5 is a cross-sectional view showing the fourth step of the manufacturing process of the floating gate flash memory formed on the partial SOI substrate as an example, for illustrating the first embodiment of this invention;

FIG. 6 is a cross-sectional view showing one step of the manufacturing process of the flash memory corresponding to the cross-sectional view of the fourth step shown in FIG. 5 as an example, for illustrating the manufacturing method of the semiconductor device of the comparison example;

FIG. 7 is a cross-sectional view showing the fifth step of the manufacturing process of the floating gate flash memory formed on the partial SOI substrate as an example, for illustrating the first embodiment of this invention;

FIG. 8 is a characteristic diagram showing the relation between the film formation rate of an O₃-TEOS film and the film formation time thereof;

FIGS. 9 to 12 are cross-sectional views showing the first to fourth steps of a manufacturing process of a floating gate flash memory formed on a bulk silicon substrate as an example, for illustrating a second embodiment of this invention;

FIGS. 13 and 14 are cross-sectional views showing the first and second steps of a manufacturing process of a charge trap flash memory formed on a partial SOI substrate as an example, for illustrating the third embodiment of this invention;

FIG. 15 is a cross-sectional view showing one step of a manufacturing process of a flash memory corresponding to the cross-sectional view of the second step shown in FIG. 14 as an example, for illustrating a manufacturing method of a semiconductor device of a comparison example;

FIGS. 16 and 17 are cross-sectional views showing the third and fourth steps of the manufacturing process of the charge trap flash memory formed on the partial SOI substrate as an example, for illustrating the third embodiment of this invention;

FIGS. 18 to 21 are cross-sectional views showing first to fourth steps of a manufacturing process of a floating gate flash memory formed on a bulk silicon substrate as an example, for illustrating the fourth embodiment of this invention;

FIG. 22 is a diagram showing an oxidation characteristic of a water radical;

FIG. 23 is a cross-sectional view showing the first step of a manufacturing process of a flash memory as an example, for illustrating the fifth embodiment of this invention;

FIGS. 24 and 25 are cross-sectional views showing the second and third steps of the manufacturing process of a flash memory having a gate dielectric film formed in advance, for illustrating the fifth embodiment of this invention;

FIGS. 26 to 28 are cross-sectional views showing the first to third steps of a manufacturing process of a logic device as an example, for illustrating the sixth embodiment of this invention;

FIGS. 29 to 32 are cross-sectional views showing the first to fourth steps of a manufacturing process of a flash memory having a gate dielectric film formed in advance as an example, for illustrating the seventh embodiment of this invention;

FIGS. 33 to 35 are cross-sectional views showing the first to third steps of a manufacturing process of a logic device as an example, for illustrating the eighth embodiment of this invention;

FIG. 36 is a schematic cross-sectional view showing the internal structures of a memory cell area and peripheral circuit area, for illustrating the ninth embodiment of this invention;

FIGS. 37 to 44 are schematic cross-sectional views showing the first to eighth manufacturing steps, for illustrating the ninth embodiment of this invention;

FIG. 45 is a schematic cross-sectional view showing a step corresponding to the fourth manufacturing step shown in FIG. 40 of the ninth embodiment, for illustrating a tenth embodiment of this invention;

FIGS. 46A and 46B, FIGS. 47A and 47B, FIGS. 48A and 48B, FIGS. 49A and 49B, FIGS. 50A and 50B, FIGS. 51A and 51B and FIGS. 52A and 52B are cross-sectional views showing the first to seventh manufacturing steps and taken in the word line direction and bit line direction, for illustrating the eleventh embodiment of this invention; and

FIGS. 53A and 53B, FIGS. 54A and 54B, FIGS. 55A and 55B, FIGS. 56A and 56B, FIGS. 57A and 57B, FIGS. 58A and 58B and FIGS. 59A and 59B are cross-sectional views showing the first to seventh manufacturing steps and taken in the word line direction and bit line direction, for illustrating the twelfth embodiment of this invention.

### DETAILED DESCRIPTION OF THE INVENTION

### First Embodiment

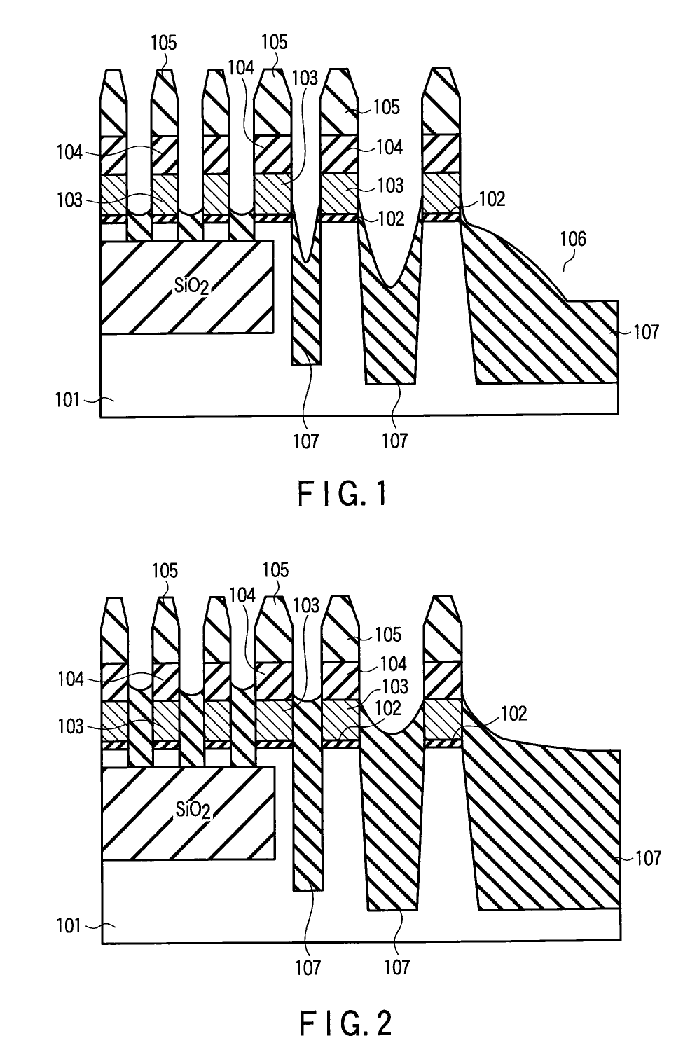

A semiconductor device and a manufacturing method thereof according to the first embodiment of this invention are explained with reference to FIGS. 1 to 7. This embodiment is an example in which a floating gate flash memory is formed on a partial SOI substrate, an O₃-TEOS film having high underlying material selectivity is formed as the first dielectric film in an isolation trench for formation of an element isolation region and then an O₃-TEOS film having no underlying material selectivity is filled therein as the second dielectric film.

According to the above system, a narrow STI portion in a cell portion is filled into a bottom-up with respect to the STI bottom portion without causing any seam. Therefore, the seam portion of the O₃-TEOS film is etched in the wet etching step performed after formation of the STI portion and a lowering in the breakdown voltage of the cell portion can be suppressed. On the other hand, since the wide STI portion in the peripheral circuit portion is mainly filled with the O₃-TEOS film at a high film deposition rate and no underlying material selectivity, the processing time can be reduced.

First, as shown in FIG. 1, a silicon thermal oxynitride film 102 with a thickness of 8 nm used as gate dielectric films, a P-doped polysilicon film 103 with a thickness of 60 nm used as floating gates and a silicon nitride film 104 with a thickness of 60 nm used as a CMP stopper are stacked on a partial SOI substrate 101. Then, a CVD silicon oxide film 105 used as a mask for reactive ion etching (RIE) is formed to a thickness of 200 nm on the entire surface of the substrate and a photoresist film (not shown) is coated on the silicon oxide film 105. After this, the photoresist film is patterned by a normal lithography technique and the silicon oxide film 105 is patterned by RIE using the photoresist film as a mask to form a hard mask. At this time, the STI width of the cell portion is approximately 40 nm, for example. The photoresist film is removed by an etching process using a hydrogen peroxide sulfuric acid mixture and ashing.

Next, the silicon nitride film 104, P-doped polysilicon film 103, silicon thermal oxynitride film 102 and partial SOI substrate 101 are sequentially patterned by an RIE process using the hard mask formed of the CVD silicon oxide film 105 to form grooves with an etching depth of approximately 220 nm in the bulk portion of the partial SOI substrate 101. Further, the residue of a reaction byproduct in the RIE step is removed by performing a process using dilute hydrofluoric acid. Thus, isolation trenches 106 used as STI regions are formed.

Then, a first O₃-TEOS film 107 is formed on the entire surface of the substrate to have a thickness of approximately 150 nm on the Si substrate. The film formation temperature of the O₃-TEOS film is 380° C. and the O₃/TEOS ratio is 9.5. Under such film formation conditions, growth of the O₃-TEOS film exhibits high underlying material dependence and almost no film formation occurs on the CVD silicon oxide film 105, silicon nitride film 104 or P-doped polysilicon film 103. Therefore, as shown in FIG. 2, the O₃-TEOS film 107 is formed in a shape as if it were selectively grown from the STI bottom portion.

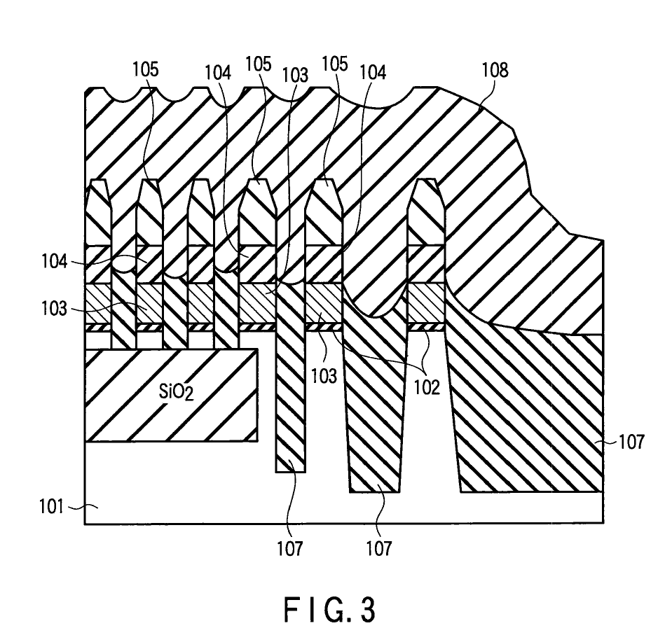

Next, as shown in FIG. 3, the second O₃-TEOS film 108 is formed in the isolation trenches 106 that are partly filled with the O₃-TEOS film 107 and thus the isolation trenches 106 are completely filled. In this case, the film formation temperature of the O₃-TEOS film is 520° C. and the O₃/TEOS ratio is 3. In this condition, the O₃-TEOS film 108 is formed in substantially a conformal form. At this time, since the narrow isolation trench is already filled almost completely with the first O₃-TEOS film 107 and the wide isolation trench is formed into a shape in which the taper angle is reduced and the film can be easily filled, the filling process can be deposited without substantially causing any seams or voids.

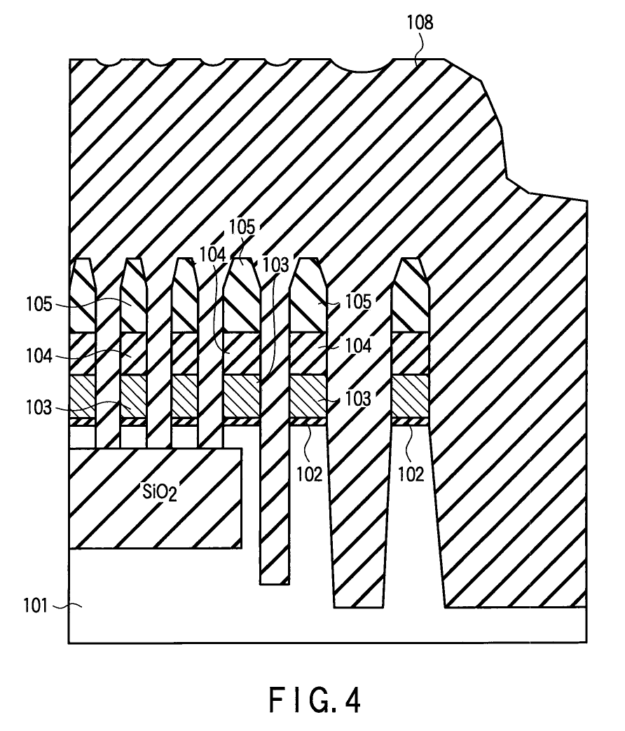

A sample in which the isolation trench was filled only with the O₃-TEOS film 108 formed at a high temperature and having no underlying material dependence was formed as a comparison example for evaluation (refer to FIG. 4).

Next, the densities of the O₃-TEOS films 107, 108 are enhanced by performing an anneal process at a temperature of approximately 900° C. for approximately 30 minutes in nitrogen ambient. Generally, oxidation in the steam atmosphere is fatal for a annealing process of an O₃-TEOS film and the substrate 101 and the P-doped polysilicon film 103 used as floating gates are oxidized in the annealing process of the O₃-TEOS film in the structure in which the gate dielectric film is formed in advance as in the present embodiment. Therefore, the effective thickness of the gate oxide film is increased and a problem that the reliability is lowered due to an increase in the write voltage and concentration of an electric field occurs.

In the present embodiment, occurrence of seams/voids is suppressed by combining two types of conditions of formation of O₃-TEOS films. Thus, since the density of the O₃-TEOS film can be enhanced merely by performing an anneal process in an inert gas such as nitrogen, the STI filling process can be attained without degrading the characteristics of the flash memory.

Next, the O₃-TEOS films 108, 107 and CVD silicon oxide film 105 are polished and left behind only in the isolation trenches 106 with the silicon nitride film 103 used as a stopper by the CMP technique.

Then, the remaining dielectric films (O₃-TEOS films 107, 108) in the isolation trenches 106 are etched back by approximately 140 nm by reactive ion etching. After this, the silicon nitride film 104 is removed in hot phosphoric acid to form STI regions.

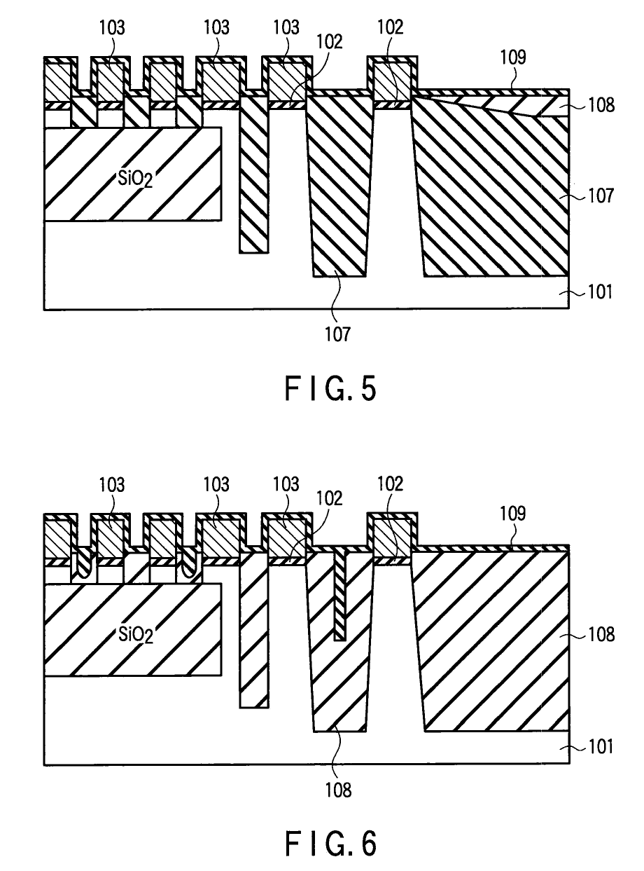

Next, as shown in FIG. 5, an ONO film 109 used as inter-polysilicon gate dielectric films (IPD) is formed. At the ONO film formation time, it is necessary to perform a pre-treatment by using a solution of a hydrofluoric acid series to remove a native oxide film on the surface of the P-doped polysilicon film 103 used as floating gates. However, in this embodiment, since the O₃-TEOS film 107 formed on the side surface of the P-doped polysilicon film 103 is grown in the bottom-up and almost no seam is formed, a phenomenon that the central portion of the STI region is etched during wet etching does not occur.

As shown in FIG. 6, in the sample in which the trench was filled with the single O₃-TEOS film formed for comparison, the central portion of the STI region was wet-etched in the pre-treatment of the ONO film and a recession was observed.

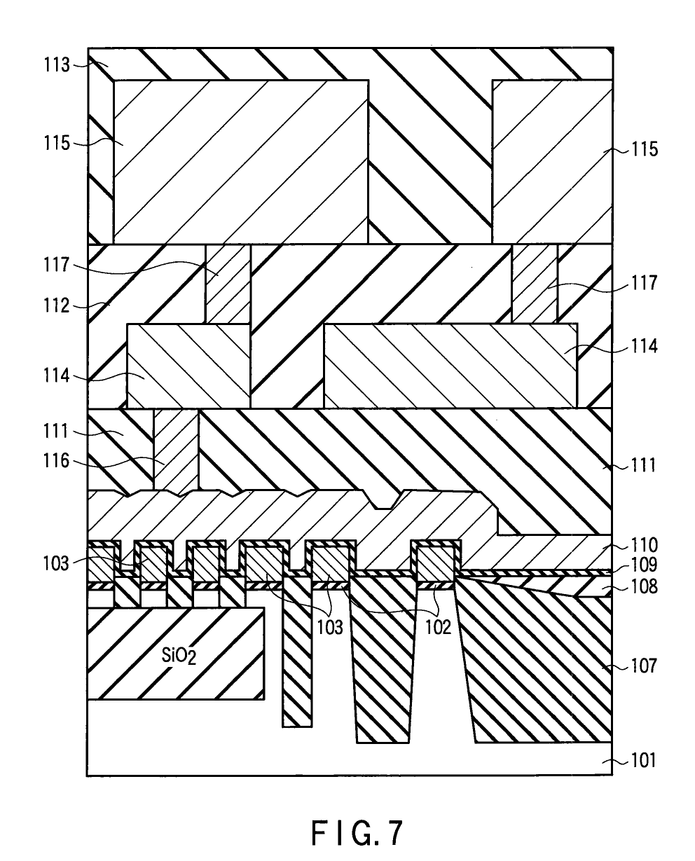

Next, as shown in FIG. 7, a P-doped polysilicon film 110 used as control gate electrodes is formed on the ONO film 109 and then the P-doped polysilicon film 110, ONO film 109 and P-doped polysilicon film 103 are sequentially patterned by a known lithography technique and RIE technique to form control gates and floating gates. In the succeeding process, inter-layer dielectric films (ILD) 111, 112, 113 are formed and interconnections 114, 115 and contact plugs 116, 117 are formed, but the detailed explanation thereof is abbreviated and only the final structure of a device is shown in FIG. 7.

In this embodiment, the isolation trench is filled with a combination of the O₃-TEOS film having high underlying material dependence and the O₃-TEOS film having low underlying material dependence and the STI region having high wet-etching resistance can be formed.

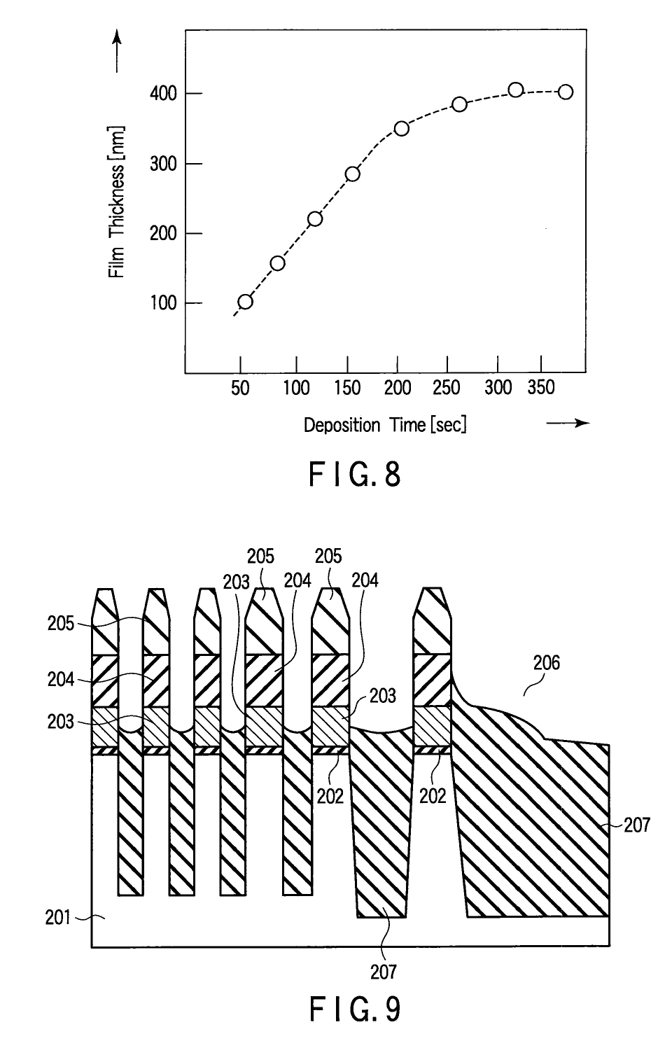

Since the film formation rate of the O₃-TEOS film is rapidly lowered when the surface of the O₃-TEOS film is separated from the underlying Si layer and if the isolation trench is filled only with the O₃-TEOS film having high underlying material dependence, the process time becomes longer. The relation between the film formation rate (Film Thickness) of the O₃-TEOS film and film formation time (Deposition Time) is shown in FIG. 8.

Therefore, as in the present embodiment, the process time can be reduced by using an O₃-TEOS film having high underlying material dependence only to fill the narrow STI portion and filling an O₃-TEOS film having a high film deposition rate and no underlying material dependence in the remaining portion of the isolation trench. An SOG film or a silicon oxide film formed by a high-density plasma-CVD method can be used instead of the O₃-TEOS film having no underlying material dependence.

### Second Embodiment

A semiconductor device and a manufacturing method thereof according to the second embodiment of this invention are explained with reference to FIGS. 9 to 12. Unlike the first embodiment, the present embodiment is an example in which an STI region is filled with an O₃-TEOS film having high underlying material selectivity, and a perhydropolysilazane film, which is a type of SOG film in a floating gate flash memory using a bulk silicon substrate. In this embodiment, an O₃-TEOS film is filled into a narrow STI portion in which the film quality of the SOG film tends to be degraded and a hybrid film of an SOG film and O₃-TEOS film is filled into a wide STI portion in which a preferable film quality can be easily attained even if an SOG film is used.

Thus, in the case of the O₃-TEOS film having high underlying material selectivity, a portion of the O₃-TEOS film whose shape is inversely tapered after filling may occur due to the influence of the undercoat state, but occurrence of poor filling can be suppressed by combining the above film with an SOG film having a superior filling property.

As shown in FIG. 9, a silicon thermal oxynitride film 202 with a thickness of 8 nm used as gate dielectric films, a P-doped polysilicon film 203 with a thickness of 50 nm used as floating gates and a silicon nitride film 204 with a thickness of 70 nm used as a CMP stopper are stacked on a semiconductor substrate (silicon substrate) 201. Then, a CVD silicon oxide film 205 used as a mask for reactive ion etching (RIE) is formed on the entire surface of the substrate and a photoresist film (not shown) is coated on the silicon oxide film 205. After this, the photoresist film is patterned by a normal lithography technique and the silicon oxide film 205 is patterned by an RIE process using the photoresist film as a mask to form a hard mask. The photoresist film is removed by an etching process using a hydrogen peroxide sulfuric acid mixture and ashing. At this time, the STI width of the cell portion is set to 30 nm, for example.

Next, the silicon nitride film 204, P-doped polysilicon film 203, silicon thermal oxynitride film 202 and semiconductor substrate 201 are sequentially processed by an RIE process using the hard mask formed of the CVD silicon oxide film 205 to form trenches with an etching depth of approximately 220 nm in the semiconductor substrate 201. Further, the residue of a reaction product in the RIE step is removed by performing a process using hydrofluoric acid. Thus, isolation trenches 206 used as STI regions are formed.

Then, an O₃-TEOS film 207 is deposited on the entire surface of the substrate to have a thickness of approximately 350 nm on the Si substrate. The film deposition temperature of the O₃-TEOS film is 410° C. and the O₃/TEOS ratio is 11. Under these film deposition conditions, growth of the O₃-TEOS film exhibits high underlying material dependence and almost no film deposition occurs on the CVD silicon oxide film 205, silicon nitride film 204 or P-doped polysilicon film 203. Therefore, the O₃-TEOS film 207 is deposited in a shape as if it were selectively grown from the STI bottom portion. Particularly, deposition of a film having high selectivity in a bottom-up is performed in the narrow isolation trench of the cell portion, and film deposition that is a combination of weak conformal growth and strong bottom-up growth is realized in the wide isolation trench of the peripheral circuit. Since the O₃-TEOS film 207 on this condition is not almost grown on the CVD silicon oxide film 205 that is a hard mask, a difference in level in the isolation trench 206 can be alleviated.

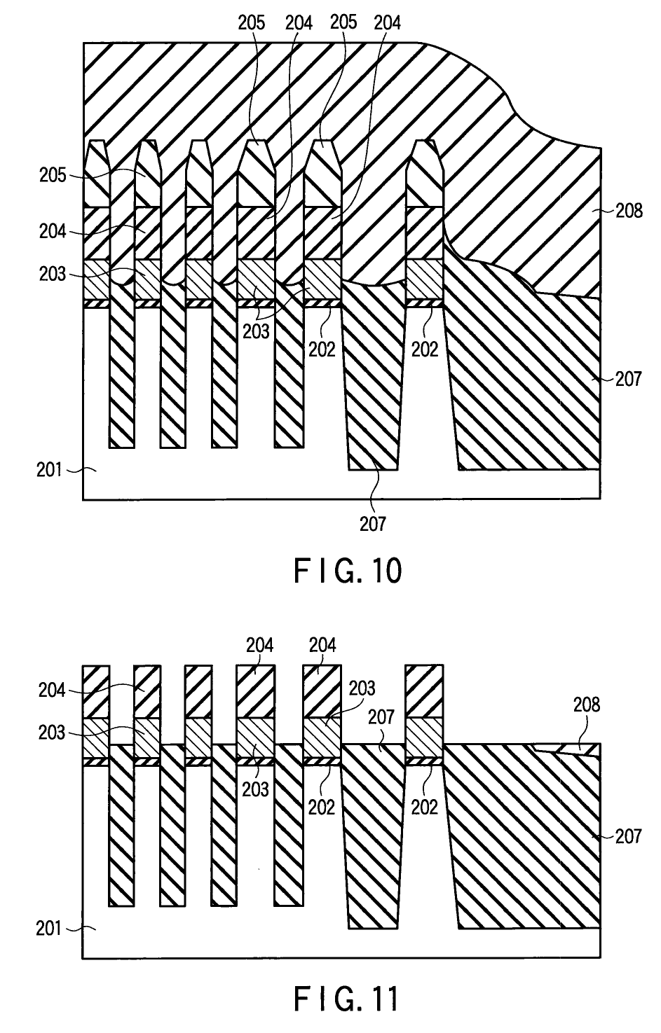

Next, as shown in FIG. 10, a polysilazane film 208 is filled on the entire surface of the substrate. A method for forming the polysilazane film is deposited as follows. A perhydropolysilazane [(SiH₂NH)ₙ] whose mean molecular weight is 2000 to 6000 is dissolved into xylene, dibutylether or the like to form a perhydropolysilazane solution and the perhydropolysilazane solution is coated on the surface of the semiconductor substrate 201 by a spin coating method. For example, the conditions of the spin coating method are that the rotation speed of the semiconductor substrate 201 is 1000 rpm, the rotation time is 30 seconds, a drop amount of the perhydropolysilazane solution is 2 cc, and the target coating film thickness immediately after baking is 300 nm. Then, the semiconductor substrate 201 having the coating film formed thereon is heated to approximately 150° C. on a hot plate and baked in an inert gas atmosphere for approximately 3 minutes to evaporate a solvent in the perhydropolysilazane solution. In this state, carbon or hydro-carbon that results from the solvent remains in the coating film as an impurity at approximately several % to several ten % and the state of the perhydropolysilazane film is set close to the state of a silicon nitride film of low density containing a residual solvent.

Nitrogen in the polysilazane film 208 is converted to nitrogen by oxidizing the perhydropolysilazane film on the condition that the oxidation amount of the silicon substrate is 0.8 nm in a low-pressure vapor atmosphere of approximately 300° C. Thus, the polysilazane film 208 is converted to a silicon oxide film. Then, the densities of the O₃-TEOS film 207 and polysilazane film 208 are enhanced by annealing the O₃-TEOS film 207 and polysilazane film 208 in N₂ of approximately 850° C. for about one hour.

Next, as shown in FIG. 11, the polysilazane film 208, O₃-TEOS film 207 and CVD silicon oxide film 205 are polished with the silicon nitride film 204 used as a stopper by the CMP technique to leave the films only in the isolation trench 206. Then, the silicon nitride film 204 is removed in hot phosphoric acid. Further, the polysilazane film 208 and O₃-TEOS film 207 in the STI portions are etched back by approximately 100 nm by reactive ion etching to form STI regions.

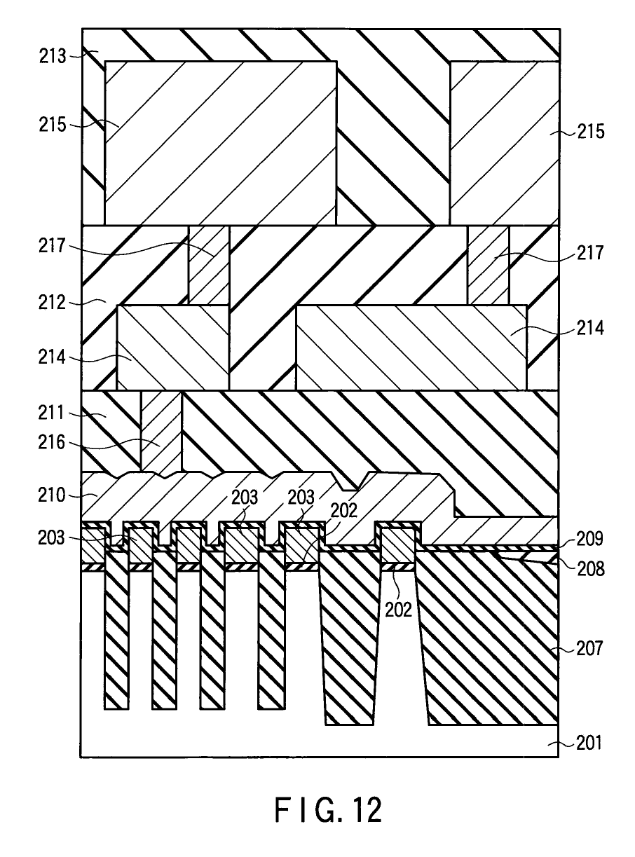

Next, as shown in FIG. 12, an ONO film 209 used as inter-polysilicon gate dielectric films (IPD) is formed. Further, a P-doped polysilicon film 210 used as control gate electrodes is formed and then the P-doped polysilicon film 210, ONO film 209 and P-doped polysilicon film 204 are sequentially patterned by a known lithography technique and RIE technique to form control gates and floating gates. In the succeeding process, inter-layer dielectric films (ILD) 211, 212, 213 are formed and interconnections 214, 215 and contact plugs 216, 217 are formed, but the detailed explanation thereof is abbreviated and only the final structure of a device is shown in FIG. 12.

There are various SOG application to STI. One is STI filled with SOG only, the other is STI filled with both SOG and conformal CVD dielectric film (silicon oxide film or silicon nitride film) liner (For example, see Japanese Patent Specification No. 3178412, Jpn. Pat. Appln. KOKAI Publications No. 2001-135718, No. 2001-267411 and No. 2005-166700). A difference with respect to the filling method for the structure of the present embodiment is as follows.

Generally, an SOG film of polysilazane, for example, causes strong tensile stress due to film shrinkage of approximately 20%. Therefore, in a case where an STI portion is filled with an SOG film only or a hybrid film of a liner dielectric film formed in a conformal form in the STI internal portion and an SOG film, the following problems (I) to (III) occur. That is, (I) a narrow isolated AA is bended or deformed due to tensile stress by the STI portion, (II) crystalline defects occur in the silicon substrate due to strong tensile stress, and (III) film peeling occurs due to strong tensile stress of the SOG film itself as the filling material. Further, the SOG film contains C caused by a solvent and N caused by a raw material, which therefore cause a problem that (IV) such impurities are thermally diffused and act as fixed charges, and an off-leak current of a transistor, particularly an N-channel transistor, is increased.

In the STI structure of this embodiment, (I) deformation of AA can be suppressed since the O₃-TEOS film is formed thick in the AA end portion and acts as a reinforcement, and (II), (III) the thickness of the coating film of the SOG film can be made thin since the effective difference in level in the isolation trench can be made small. Therefore, the tensile stress can be suppressed and occurrence of crystalline defects and film peeling can be suppressed. (IV) Since the SOG film can be made thin and impurities in the SOG film can be easily removed by annealing, the effect that occurrence of fixed charges can be suppressed and the off-leak current of the transistor is improved can be attained. A comparison table of the transistor characteristics based on the method used in this embodiment and the method of filling the STI portion with only the SOG film (coating polysilazane to 600 nm) is shown below.

TABLE 1

| | this embodiment | comparison example |
|---|---|---|
| | (O₃-TEOS liner having | (filling the |
| | high underlying | STI portion) |
| | material selectivity) | coating |
| | coating polysilazane | polysilazane |
| | to 300 nm | to 600 nm |
| N-channel transistor | 21.9 pA/Tr | 162.8 pA/Tr |
| P-channel transistor | 27.8 pA/Tr | 314.4 pA/Tr |

It is understood from the comparison table 1 that the off-leak currents of the N-channel transistor, which is easily influenced by fixed charges, and the P-channel transistor, which is easily influenced by crystalline defects, can be reduced by utilizing the second embodiment.

### Third Embodiment

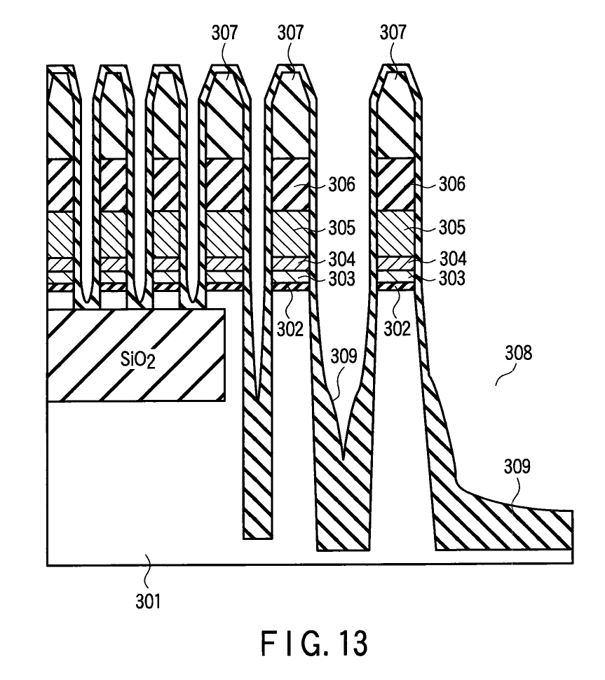

A semiconductor device and a manufacturing method thereof according to a third embodiment of this invention are explained with reference to FIGS. 13 to 17. This embodiment is an example applied to a charge trap flash memory formed on a partial SOI substrate. In this embodiment, a cell portion of the flash memory is filled with an O₃-TEOS film having high underlying material selectivity in a liner form, a wide STI portion of the peripheral circuit portion is filled in a bottom-up form and the STI portion is completely filled by using the film in combination with the SOG film. As is explained in the second embodiment, it is possible to attain the effect that fixed charges and stress can be alleviated by reducing the coating film thickness of the SOG film due to formation of the wide STI portion in the bottom-up form.

As shown in FIG. 13, a silicon thermal oxynitride film 302 with a thickness of 4 nm used as gate dielectric films, a silicon nitride film 303 with a thickness of 10 nm used as a charge trap layer, an alumina film 304 with a thickness of 15 nm used as an insulating layer to suppress the occurrence of charge leak currents, a P-doped polysilicon film 305 with a thickness of 40 nm used as part of control gate electrodes and a silicon nitride film 306 with a thickness of 60 nm used as a CMP stopper are stacked and formed on a partial SOI substrate 301. Then, a CVD silicon oxide film 307 used as a hard mask for reactive ion etching (RIE) is formed to a thickness of 200 nm on the entire surface of the substrate, and a photoresist film (not shown) is coated and formed on the silicon oxide film 307. Subsequently, the photoresist film is patterned by a normal lithography technique and the silicon oxide film 307 is patterned by an RIE process using the photoresist film as a mask to form a hard mask. At this time, the STI width of the cell portion is approximately 25 nm, for example. The photoresist film is removed by an etching process using a hydrogen peroxide sulfuric acid mixture and ashing.

Next, the silicon nitride film 306, P-doped polysilicon film 305, alumina film 304, silicon nitride film 303, silicon thermal oxynitride film 302 and partial SOI substrate 301 are sequentially patterned by an RIE process using the hard mask formed of the CVD silicon oxide film 307 to form trenches with an etching depth of approximately 220 nm in the bulk portion of the partial SOI substrate 301. Further, the residual of a reaction byproduct in the RIE step is removed by performing a process using dilute hydrofluoric acid. Thus, isolation trenches 308 used as STI regions are formed.

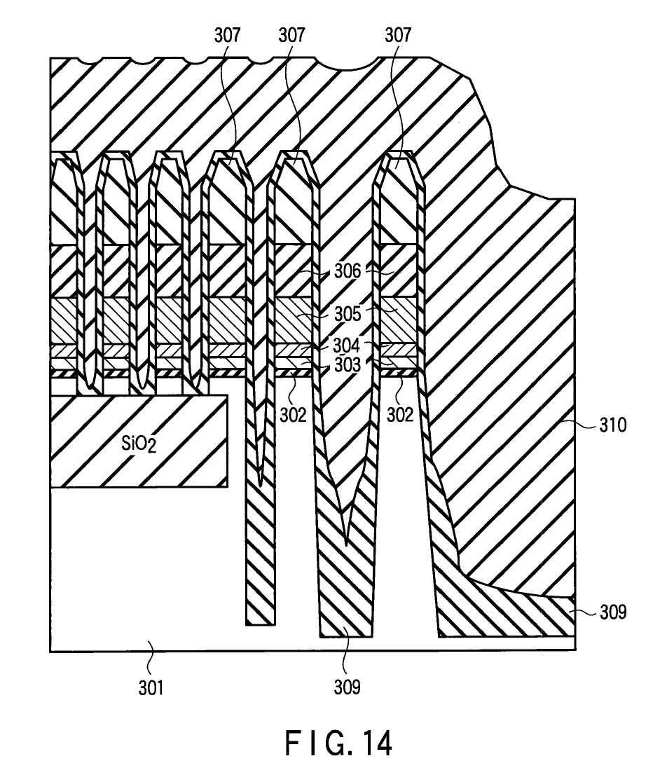

Next, as shown in FIG. 14, an O₃-TEOS film 309 is formed on the entire surface of the substrate to have a thickness of approximately 150 nm on the Si substrate. At this time, the film formation temperature of the O₃-TEOS film is 460° C. and the O₃/TEOS ratio is 8. Under these film formation conditions, growth of the O₃-TEOS film exhibits underlying material dependence, but since the film deposition temperature is high in comparison with a case of the first embodiment, the selectivity in the narrow isolation trench of a memory cell portion is lowered and deposition is performed to deposit the film in a combined form of a bottom-up form and conformal form. Therefore, film formation in a form close to the conformal form occurs at a low film deposition rate on the CVD silicon oxide film 307, silicon nitride film 306, P-doped polysilicon film 305, alumina film 304 and silicon nitride film 303. At this time, film deposition occurs in the Si portion at a film deposition rate at least five times higher than the above film deposition rate. Therefore, the O₃-TEOS film 309 is deposited in a shape as if it were selectively grown from the STI bottom portion.

Next, a polysilazane film 310 is filled in the isolation trenches 308 that are partly filled with the O₃-TEOS film 309. The polysilazane film formation condition is the same as that described in the second embodiment. However, since the film thickness of the O₃-TEOS film 309 formed in this embodiment is thinner than that in the second embodiment, the thickness of the coating film of polysilazane is set to approximately 400 nm.

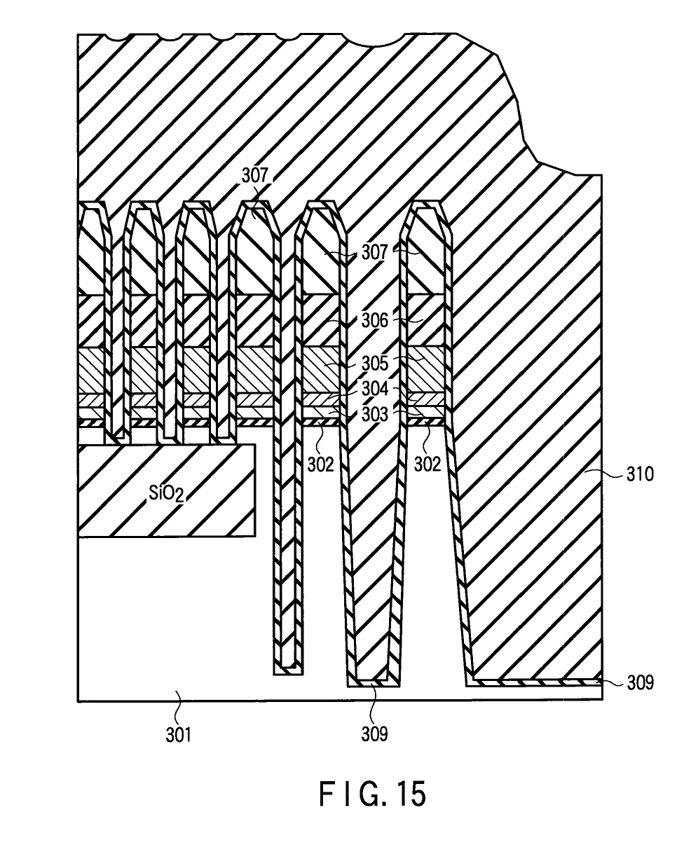

Further, as shown in FIG. 15, a sample in which the O₃-TEOS film 309 was deposited on the same condition as that of deposition of the O₃-TEOS film having no underlying material selectivity in the first embodiment and the STI region that was completely filled with the polysilazane film was formed as a comparison example for evaluation. In this case, the coating film thickness of the polysilazane film was set to approximately 550 nm.

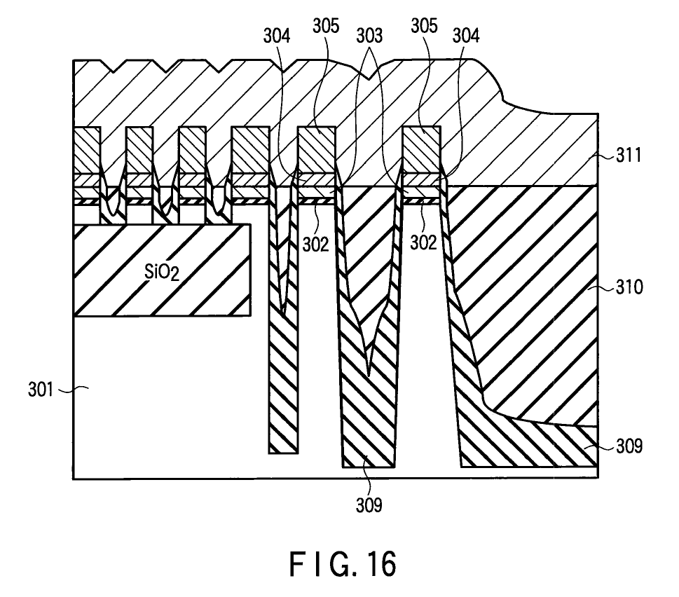

Next, an anneal process is performed at a temperature of approximately 900° C. for approximately 30 minutes in nitrogen to enhance the densities of the polysilazane film 310 and O₃-TEOS film 309. Then, the polysilazane film 310 and O₃-TEOS film 309 are polished with the silicon nitride film 306 used as a stopper by the CMP technique to be left only in the internal portions of the isolation trenches 308 as shown in FIG. 16. Subsequently, the filling dielectric film (polysilazane film 310 and O₃-TEOS film 309) left in the isolation trenches 308 is etched back by approximately 60 nm by reactive ion etching. Then, the silicon nitride film 306 is removed in hot phosphoric acid to from STI regions.

Next, a P-doped polysilicon film 311 used as control gate electrodes is deposited. In the pre-treatment for the P-doped polysilicon film 311, it is necessary to perform a pre-treatment by using a solution of a hydrofluoric acid series to remove native oxide films on the surfaces of the P-doped polysilicon films 305. In this embodiment, the STI portion is formed in a form in which the central portion thereof is slightly recessed since the wet-etching rate of the polysilazane film 310 is higher than that of the O₃-TEOS film 309, but the form itself reduces the parasitic capacitance between the adjacent cells and is effective in preventing interference between the cells.

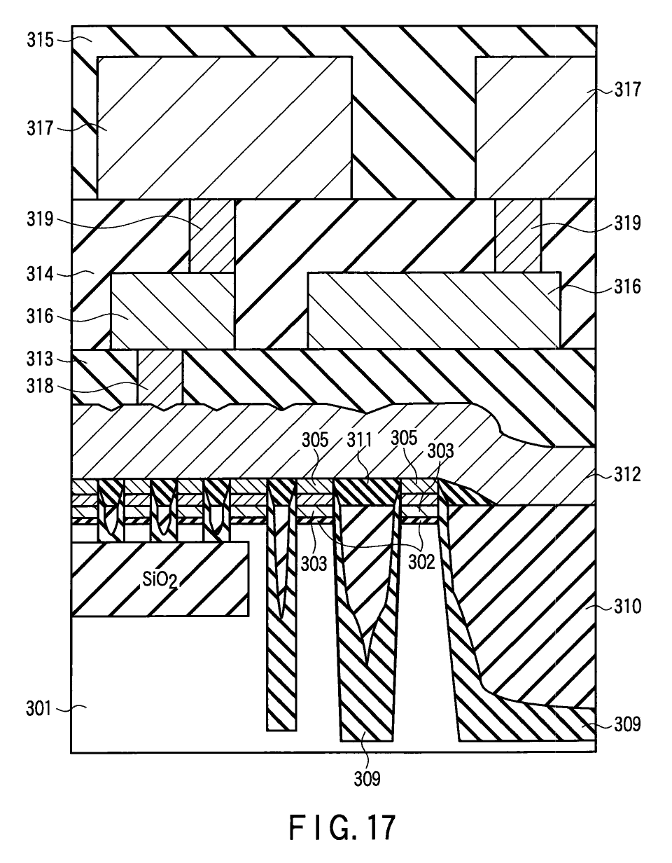

Next, as shown in FIG. 17, the P-doped polysilicon films 311, 305 are patterned by a known lithography technique and RIE technique. Further, a nickel film is formed on the entire surface of the substrate by sputtering and part of the nickel film that is not reacted after silicidation annealing is etched off by use of a hydrogen peroxide sulfuric acid mixture to form a nickel silicide electrode 312. Thus, the control gates and charge trap layers are formed. In the succeeding process, pre-metal dielectric films (PMD) 313, 314, 315 are formed and interconnections 316, 317 and contact plugs 318, 319 are formed, but the detailed explanation thereof is abbreviated and only the final structure of a device is shown in FIG. 17.

Like the second embodiment, in the present embodiment, the coating film thickness of the SOG film can be made thinner in comparison with a case wherein the CVD dielectric film formed in a normal conformal form is used for the liner. Thus, an advantage that the stress caused by the SOG film can be alleviated, occurrence of crystalline defects/film cracking/film peeling due to the reduction in the stress can be suppressed and occurrence of fixed charges due to the presence of impurities (C, N and the like) caused by the SOG film can be suppressed is obtained.

A comparison table of the transistor characteristics based on the method used in this embodiment and the method in which the O₃-TEOS film having no undercoat selectivity and used as a comparison example for evaluation is used as a liner is shown below.

TABLE 2

| | | comparison example |
|---|---|---|
| | this embodiment | (O₃-TEOS liner |
| | (O₃-TEOS liner having | having no |
| | high underlying | underlying material |
| | material selectivity) | selectivity) |
| | coating polysilazane | coating polysilazane |
| | to 400 nm | to 550 nm |
| N-channel transistor | 40.3 pA/Tr | 112.8 pA/Tr |
| P-channel transistor | 52.6 pA/Tr | 254.4 pA/Tr |

It is understood from the comparison table 2 that the off-leak currents of the N-channel transistor, which is easily influenced by fixed charges, and the P-channel transistor, which is easily influenced by crystalline defects, can be reduced by use of the method of this embodiment.

### Fourth Embodiment

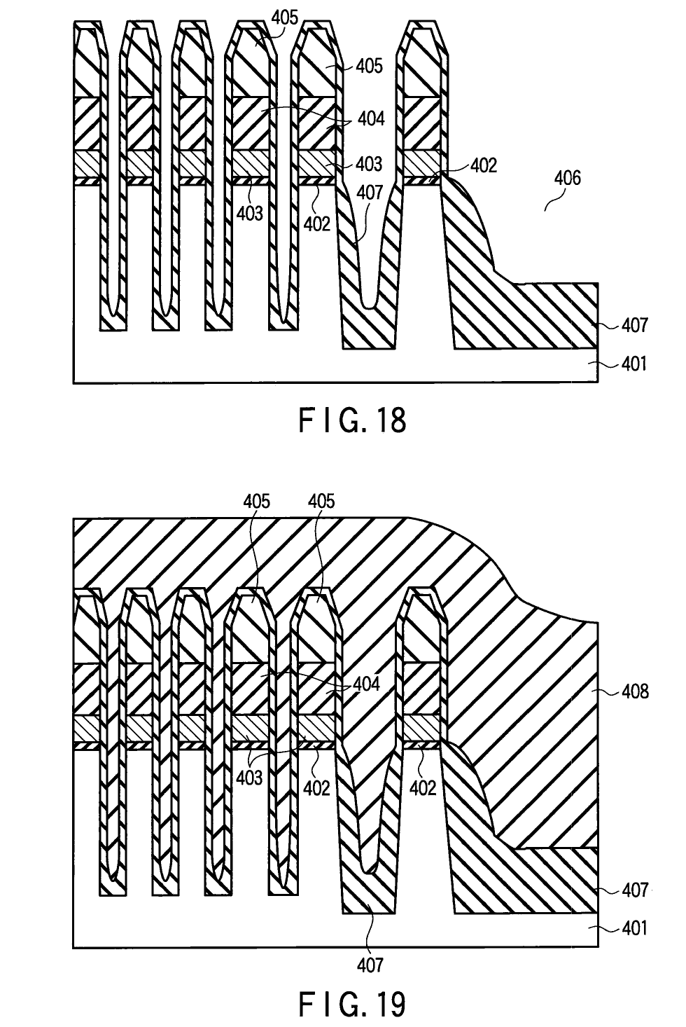

A semiconductor device and a manufacturing method thereof according to a fourth embodiment of this invention are explained with reference to FIGS. 18 to 21. This embodiment is an example applied to a floating gate flash memory formed on a bulk silicon substrate. In this embodiment, an STI region is filled with an O₃-TEOS film having high underlying material selectivity, and a perhydropolysilazane film, which is a type of SOG film. Unlike the second embodiment, the O₃-TEOS film having high underlying material dependence is filled in the cell portion of the flash memory in a liner form as in the third embodiment and filled in wide STI portions of the peripheral circuit portion in a form similar to a bottom-up form to completely fill the STI region in combination with the SOG film.

First, as shown in FIG. 18, a silicon thermal oxynitride film 402 with a thickness of 8 nm used as gate dielectric films, a P-doped polysilicon film 403 with a thickness of 40 nm used as floating gates, and a silicon nitride film 404 with a thickness of 70 nm used as a CMP stopper are stacked on a semiconductor substrate (silicon substrate) 401. Then, a CVD silicon oxide film 405 used as a mask for reactive ion etching (RIE) is deposited to a thickness of 150 nm on the entire surface of the substrate and a photoresist film (not shown) is coated and formed on the silicon oxide film 405. Subsequently, the photoresist film is patterned by a normal lithography technique and the silicon oxide film 405 is patterned by an RIE process using the photoresist film as a mask to form a hard mask. The photoresist film is removed by an etching process using a hydrogen peroxide sulfuric acid mixture and ashing. At this time, the STI width in the cell portion is approximately 40 nm, for example.

Next, the silicon nitride film 404, P-doped polysilicon film 403, silicon thermal oxynitride film 402 and semiconductor substrate 401 are sequentially processed by an RIE process using the hard mask formed of the CVD silicon oxide film 405 to form trenches with an etching depth of approximately 220 nm in the semiconductor substrate 401. Further, the residual of a reaction byproduct in the RIE step is removed with dilute hydrofluoric acid. Thus, isolation trenches 406 used as STI regions are formed.

Next, as shown in FIG. 19, the first O₃-TEOS film 407 is deposited on the entire surface of the substrate to have a thickness of approximately 150 nm on the Si substrate. At this time, the film deposition temperature of the O₃-TEOS film is 450° C. and the O₃/TEOS ratio is 13. Also, in this film deposition condition, growth of the O₃-TEOS film exhibits underlying material dependence, but since the film deposition temperature is high, the film is deposited in substantially a conformal form on the CVD silicon oxide film 405, silicon nitride film 404 and P-doped polysilicon film 403 and is formed in a shape as if the O₃-TEOS film 407 were selectively grown from the STI bottom portion on the Si substrate. Like the embodiments explained so far, since the O₃-TEOS film 407 is not substantially grown on the CVD silicon oxide film 405 that is the hard mask, a difference in level in the isolation trench 406 is reduced.

Next, a polysilazane film 408 is formed on the entire surface of the substrate to fill the isolation trenches 406. The method of forming the polysilazane film is the same as that explained in the second and third embodiments, and therefore, the explanation thereof is abbreviated. In this case, the thickness of the polysilazane film is approximately 400 nm.

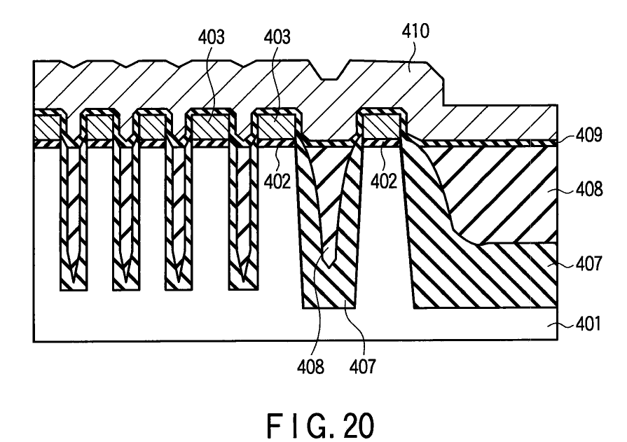

Next, as shown in FIG. 20, the polysilazane film 408, O₃-TEOS film 407 and CVD silicon oxide film 405 are polished with the silicon nitride film 404 used as a stopper by use of the CMP technology and left only in the internal portions of the isolation trenches 406. Then, the silicon nitride film 404 is removed in hot phosphoric acid. Further, the polysilazane film 408 and O₃-TEOS film 407 in the STI portions are etched back by approximately 80 nm by reactive ion etching to form STI regions.

Next, an ONO film 409 used as an inter-polysilicon gate dielectric film (IPD) and a P-doped polysilicon film 410 used as control gate electrodes are formed. In a pre-process at the time of formation of the ONO film 409, a wet etching process using a hydrofluoric acid series is performed. In this case, since the wet-etching rate of a polysilazane film is higher than that of an O₃-TEOS film, the STI central portion is recessed. If the ONO film 409 and P-doped polysilicon film 410 are sequentially formed on the resultant structure, portions of the P-doped polysilicon film 410 are filled into the STI portions to electrically isolate the adjacent cells from each other.

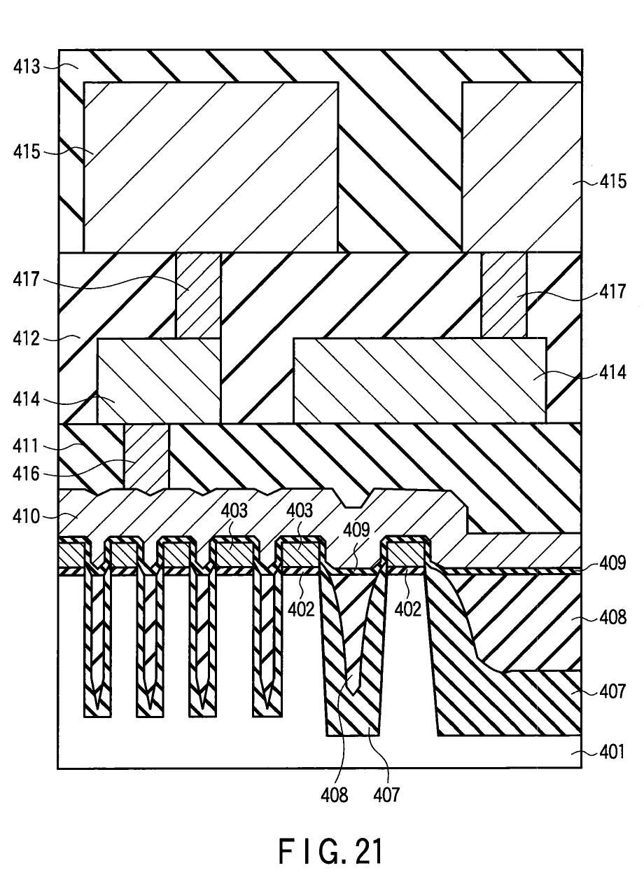

Next, as shown in FIG. 21, the P-doped polysilicon film 410, ONO film 409 and P-doped polysilicon film 404 are sequentially processed by the known lithography technique and RIE technique to form control gates and floating gates. In the succeeding process, pre-metal dielectric films (PMD) 411, 412, 413 are formed and interconnections 414, 415 and contact plugs 416, 417 are formed, but the detailed explanation thereof is abbreviated and only the final structure of a device is shown in FIG. 21.

Like the third embodiment, in the present embodiment, the coating film thickness of the SOG film can be made thinner in comparison with a case wherein the CVD dielectric film deposited in a normal conformal form is used for the liner. Thus, an advantage that the stress caused by the SOG film can be alleviated, occurrence of crystalline defects/film cracking/film peeling due to the reduction in the stress can be suppressed and occurrence of fixed charges due to the presence of impurities (C, N and the like) caused by the SOG film can be suppressed is obtained. In addition, since the wet-etching rate of the polysilazane film 408 is higher than that of the O₃-TEOS film 407, an advantage that the STI central portion is slightly recessed to reduce the capacitive coupling between adjacent cells and suppress interference between cells is obtained.

As described above, the first to fourth embodiments are shown. However, the method of this invention is not limited to the combinations described in the embodiments and the same effect can be realized by adequately combining the method of filling the STI portions, the substrate structure and the storage method of the flash memory.

As described above, in the first to fourth embodiments, a manufacturing method of the STI region with a preferable characteristic and a flash memory with a preferable element characteristic can be provided by using a high selective (low temperature) condition with respect to an underlying O₃-TEOS film to non-uniformly form a first dielectric film in the isolation trenches of the STI portions and then completely fill the isolation trenches in cooperation with the second dielectric film that is subsequently formed. Further, according to the above embodiments, extremely small STI portions can be formed, and therefore, the performance of the flash memory can be enhanced by further downsizing of the flash memory.

### Fifth Embodiment

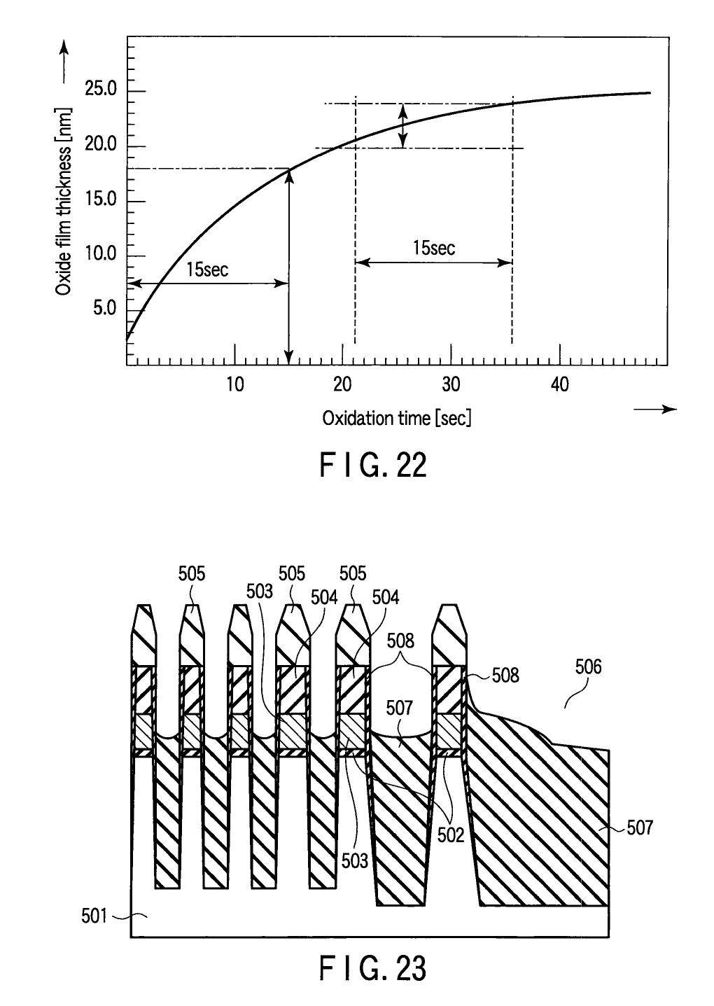

A semiconductor device and a manufacturing method thereof according to the fifth embodiment of this invention are explained with reference to FIGS. 22 to 25. This embodiment is an example applied to a flash memory having a gate dielectric film formed in advance. According to this method, it becomes possible to attain slimming due to oxidation of an active area while oxidation of a bird's beak obtained by oxidizing the bottom portion of a floating gate in a bird's beak form is suppressed.

First, as shown in FIG. 23, a silicon thermal oxynitride film 502 with a thickness of 8 nm used as gate dielectric films, a P-doped polysilicon film 503 with a thickness of 60 nm used as floating gates and a silicon nitride film 504 with a thickness of 60 nm used as a CMP stopper are stacked on a semiconductor substrate 501. Then, a CVD silicon oxide film 505 used as a mask for reactive ion etching (RIE) is deposited to a thickness of 200 nm on the entire surface of the substrate and a photoresist film (not shown) is coated and formed on the silicon oxide film 505. After this, the photoresist film is patterned by a normal lithography technique and the silicon oxide film 505 is patterned by an RIE process using the photoresist film as a mask to form a hard mask. At this time, the STI width and AA width of the cell portion are each set to approximately 40 nm. The photoresist film is removed by an etching process using a hydrogen peroxide sulfuric acid mixture and ashing.

Next, the silicon nitride film 504, P-doped polysilicon film 503, silicon thermal oxynitride film 502 and semiconductor substrate 501 are sequentially patterned by an RIE process using the hard mask formed of the CVD silicon oxide film 505 to form trenches with a depth of approximately 220 nm. Further, the residual of a reaction byproduct in the RIE step is removed with dilute hydrofluoric acid. Thus, isolation trenches 506 used as STI regions are formed.

Next, the first O₃-TEOS film 507 is deposited on the entire surface of the substrate to have a thickness of approximately 150 nm on the Si substrate. At this time, the film deposition temperature of the O₃-TEOS film is 380° C. and the O₃/TEOS ratio is 9.5. Under these film deposition conditions, growth of the O₃-TEOS film exhibits high underlying material dependence and almost no film deposition occurs on the CVD silicon oxide film 505, silicon nitride film 504 or P-doped polysilicon film 503. Therefore, the O₃-TEOS film 507 is deposited in a shape as if it were selectively grown from the STI bottom portion. Then, a process of oxidation is performed over the O₃-TEOS film 507 at a temperature of 1000° C. in a mixed gas of hydrogen/oxygen to eliminate defects caused at the processing time of the isolation trenches by forming a silicon thermal oxide film 508 and perform slimming for the active area.

In the above atmosphere, water radicals are formed by a reaction of hydrogen with oxygen. The oxidation characteristic of the water radical is shown in FIG. 22. In this embodiment, since the distance from the surface of the O₃-TEOS film 507 to the internal surface of the isolation trench of the cell portion is 20 nm or more, the rate of increase of the oxidation amount remains low even if the oxidation time is increased. Under the above condition, the bird's beak oxidation in which an oxidizing agent is diffused into the bottom portion of the floating gate to oxidize the same in a bird's beak form hardly occurs and the oxidation amount can be easily controlled. In this embodiment, oxidation of approximately 4 nm over the O₃-TEOS film 507 and oxidation of approximately 4 nm in the slimming amount of the active area were realized in the oxidation condition of 18 nm on TP by the water radical oxidation.

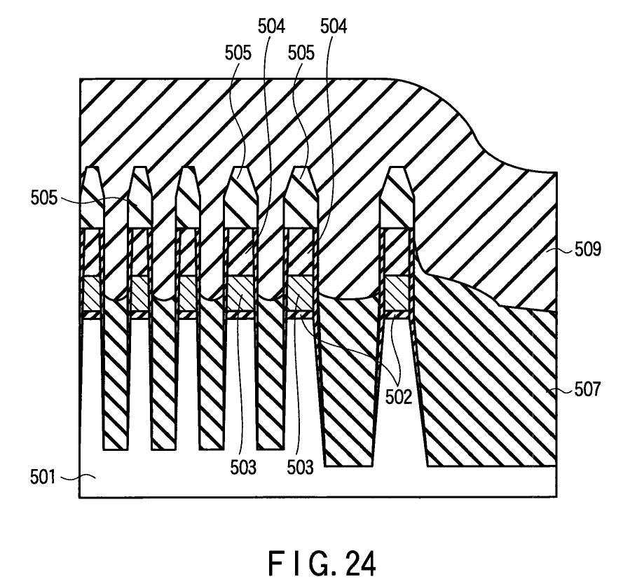

Next, as shown in FIG. 24, the second O₃-TEOS film 509 is deposited in the isolation trenches 506 that are partly filled with the O₃-TEOS film 507 to completely fill the isolation trenches 506. In this case, the film deposition temperature of the O₃-TEOS film is 520° C. and the O₃/TEOS ratio is 3. Under these conditions, the O₃-TEOS film 509 is deposited in substantially a conformal form. Since the narrow isolation trench is already filled almost completely with the first O₃-TEOS film and the wide isolation trench is formed into a shape in which the taper angle is reduced and the film can be easily filled, the filling process can be performed without substantially causing any seams or voids.

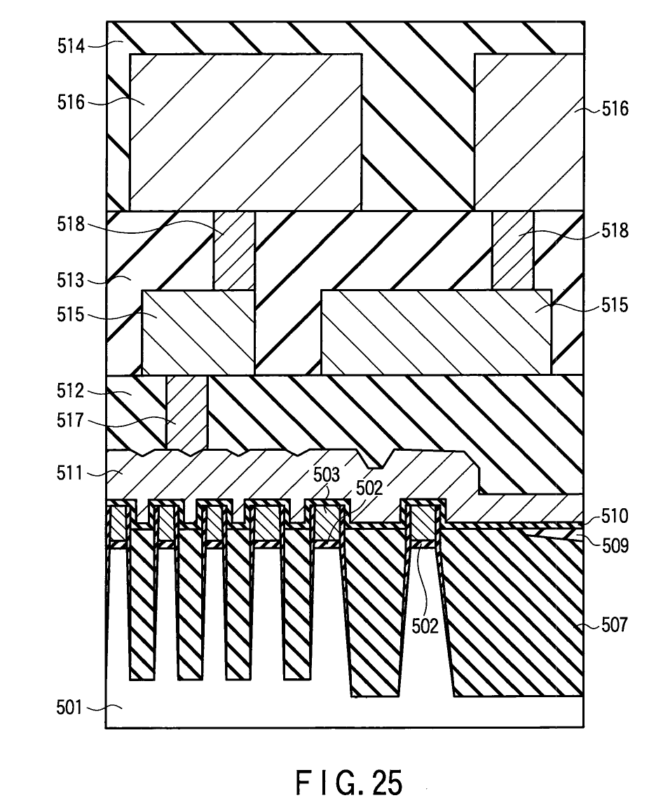

Then, as shown in FIG. 25, an anneal process is performed at a temperature of 900° C. for 30 minutes in nitrogen to enhance the densities of the O₃-TEOS films 507, 509. Generally, oxidation in the steam atmosphere is fatal in the heating process of the O₃-TEOS film. In the structure in which the gate dielectric film is previously formed as in this embodiment, the substrate 501 and the P-doped polysilicon film 503 used as floating gates are oxidized during the annealing process of the O₃-TEOS film, the effective gate oxide film thickness is increased and a problem of degradation in the reliability due to an increase in the write voltage and concentration of the electric field may occur. However, in this embodiment, since the density of the O₃-TEOS film can be enhanced merely by performing an anneal process using an inert gas such as nitrogen by combining two types of O₃-TEOS conditions to suppress the occurrence of seams/voids, the STI filling process can be performed without degrading the characteristic of the flash memory.

Next, the O₃-TEOS films 507, 509 and CVD silicon oxide film 505 are polished with the silicon nitride film 504 used as a stopper by the CVD technique and the films are left only in the internal portions of the isolation trenches 506.

Subsequently, the STI height is adjusted by reactive ion etching and then the silicon nitride film 504 is removed in hot phosphoric acid to from STI regions. Next, an ONO film 510 used as an inter-polysilicon gate dielectric film (IPD) and a P-doped polysilicon film 511 used as control gate electrodes are formed and the P-doped polysilicon film 511, ONO film 510 and P-doped polysilicon film 103 are sequentially patterned to form control gates and floating gates by a known lithography technique and RIE technique. In the succeeding process, inter-layer dielectric films (ILD) 512, 513, 514 are formed and interconnections 515, 516 and contact plugs 517, 518 are formed, but the detailed explanation thereof is abbreviated and only the final structure of a device is shown in FIG. 25.

With the structure and manufacturing method of this embodiment, substantially the same operation and effect as those of the above embodiments can be attained.

In this embodiment, the O₃-TEOS film having no underlying material dependence is used as the second dielectric film. However, since the narrow STI portion is substantially filled after the O₃-TEOS film having high undercoat dependence and used as the first dielectric film is filled and the wide STI portion is formed with the bottom portion raised and formed into a forward tapered form in which the second dielectric film can be easily filled, the remaining portion of the isolation trench can be filled with an HDP-CVD silicon oxide film, LPCVD silicon oxide film or SOG film.

### Sixth Embodiment

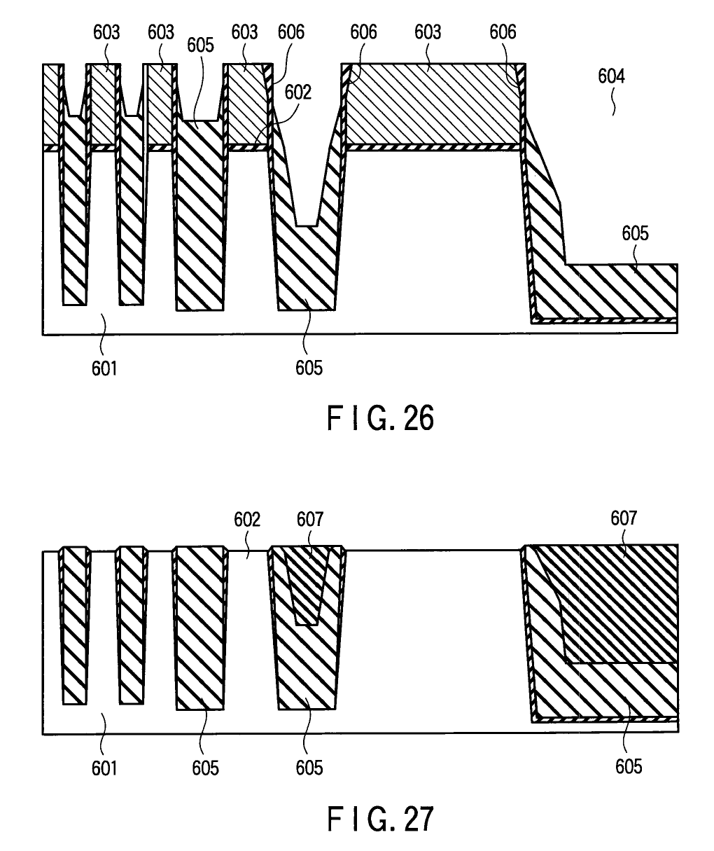

A semiconductor device and a manufacturing method thereof according to the sixth embodiment of this invention are explained with reference to FIGS. 26 to 28. This embodiment is an example of a logic device in which an STI portion is filled with an O₃-TEOS film having high underlying material selectivity and an HDP-CVD silicon oxide film.

First, as shown in FIG. 26, a silicon thermal oxide film 602 with a thickness of 4 nm used as a sacrificial oxide film and a silicon nitride film 603 with a thickness of 100 nm used as a CMP stopper are formed on a semiconductor substrate 601. Then, a CVD silicon oxide film (not shown) used as a mask for reactive ion etching (RIE) is formed on the entire surface of the substrate and a photoresist film (not shown) is coated thereon. Next, the photoresist film is patterned by a normal lithography technique and the silicon oxide film is patterned by an RIE process using the photoresist film as a mask to form a hard mask. The photoresist film is removed by an etching process using a hydrogen peroxide sulfuric acid mixture and ashing. At this time, the STI width and AA width of the cell portion are respectively set to 50 nm and 40 nm.

Next, the silicon nitride film 603, silicon thermal oxide film 602 and semiconductor substrate 601 are sequentially patterned by an RIE process using the hard mask formed of the CVD silicon oxide film 604 to form trenches with an etching depth of approximately 300 nm in the semiconductor substrate 601. Further, the residuals of a reaction byproduct in the RIE step and the CVD silicon oxide film are removed by performing a wet process. Thus, isolation trenches 604 used as STI regions are formed. In this embodiment, it is possible to attain an advantage that collapse of patterns and peeling of patterns can be suppressed by setting the AA width to a slightly large size of 50 nm.

Next, an O₃-TEOS film 605 is deposited on the entire surface of the substrate to have a thickness of approximately 160 nm on the Si substrate. In this case, the film deposition temperature of the O₃-TEOS film is 410° C. and the O₃/TEOS ratio is 11. Also, in the film deposition condition, growth of the O₃-TEOS film exhibits high underlying material dependence and almost no film deposition occurs on the silicon nitride film 603 or silicon thermal oxide film 602. Therefore, the O₃-TEOS film 605 is deposited in a shape as if it were grown from the STI bottom portion in a combined method of selective growth and conformal growth. Then, a process of oxidation is performed over the O₃-TEOS film 605 at a temperature of 950° C. in a mixed gas of hydrogen/oxygen to eliminate defects caused at the processing time of the isolation trench by forming a silicon thermal oxide film 606 and perform slimming for the active area. In the above embodiment, oxidation of approximately 6 nm over the O₃-TEOS film 605 and oxidation of approximately 4 nm in the slimming amount of the active area were performed to realize an active area width of 45 nm in the oxidation condition of 20 nm on TP by the water radical oxidation.

Next, as shown in FIG. 27, an HDP-CVD silicon oxide film 607 is formed on the entire surface of the substrate to fill the isolation trenches 604. The coverage of the HDP-CVD silicon oxide film 607 used here is highly dependent on the remaining unfilled trench shape. However, since the O₃-TEOS film 605 exhibiting high underlying material dependence is deposited and the bottom of the isolation trench 604 is raised in a forward tapered form, the HDP-CVD silicon oxide film 607 can be relatively easily filled without causing any voids.

Next, the HDP-CVD silicon oxide film 607 and O₃-TEOS film 605 are polished and left behind only in the isolation trench 604 with the silicon nitride film 603 used as a stopper by the CMP technique. Further, the films are wet-etched back to adjust the height of the STI portion by using buffered hydrofluoric acid. Then, the silicon nitride film 603 is removed in hot phosphoric acid and the silicon thermal oxide film 602 is separated by a wet-etching process using a hydrofluoric acid series to from STI regions.

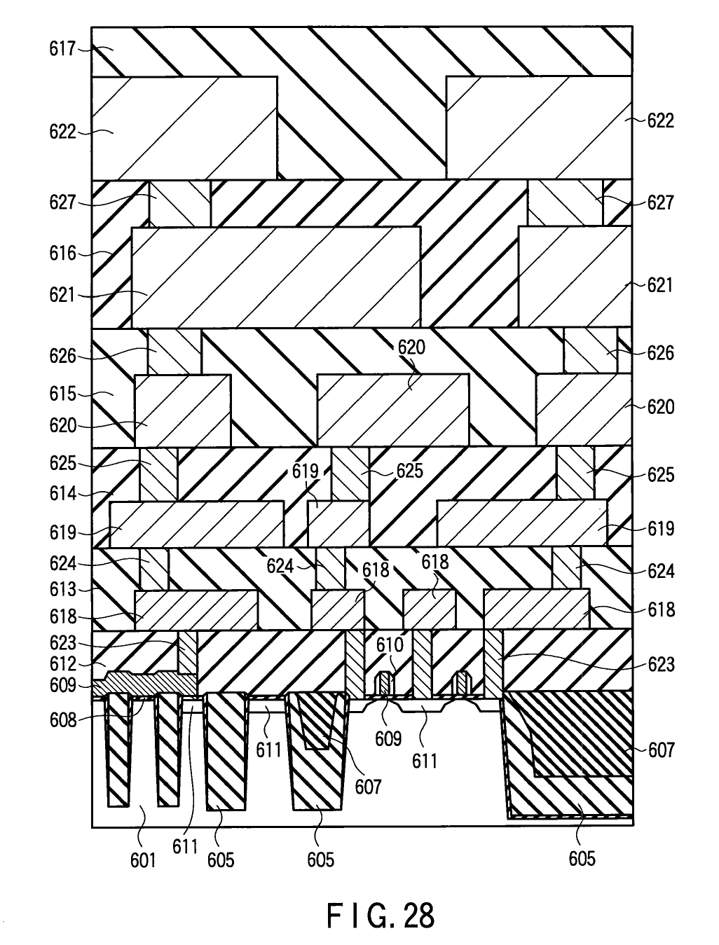

Subsequently, as shown in FIG. 28, gate dielectric films 608, gate electrodes 609, sidewall spacers 610 and diffusion layers 611 are formed to form transistors. In the succeeding process, inter-layer dielectric films or pre-metal dielectric films (ILD/PMD) 612, 613, 614, 615, 616, 617 are formed and interconnections 618, 619, 620, 621, 622 and contact plugs 623, 624, 625, 626, 627 are formed, but the detailed explanation thereof is abbreviated and only the final structure of a device is shown in FIG. 28.

The fifth and sixth embodiments are explained above, but the method of this invention is not limited to the combinations described in the above embodiments and the same effect can be attained by adequately combining the device, STI filling method, AA oxidizing method and the like.

According to the fifth and sixth embodiments, the high selective (low temperature) condition with respect to an underlying O₃-TEOS film is used, the first dielectric film formed with substantially no seam is formed in the STI isolation trench and an AA oxidizing process is performed over the first dielectric film to suppress diffusion of the oxidizing agent in the lateral direction and oxidize only the uppermost surface of the isolation trench. Then, the second dielectric film is formed on the first dielectric film to fill the isolation trench and thus an STI forming method in which erosion due to oxidation of the AA region is prevented can be provided. Further, according to this embodiment, since extremely small STI portions can be formed, the flash memory and logic device can be further downsized and the performance thereof can be further enhanced.

### Seventh Embodiment

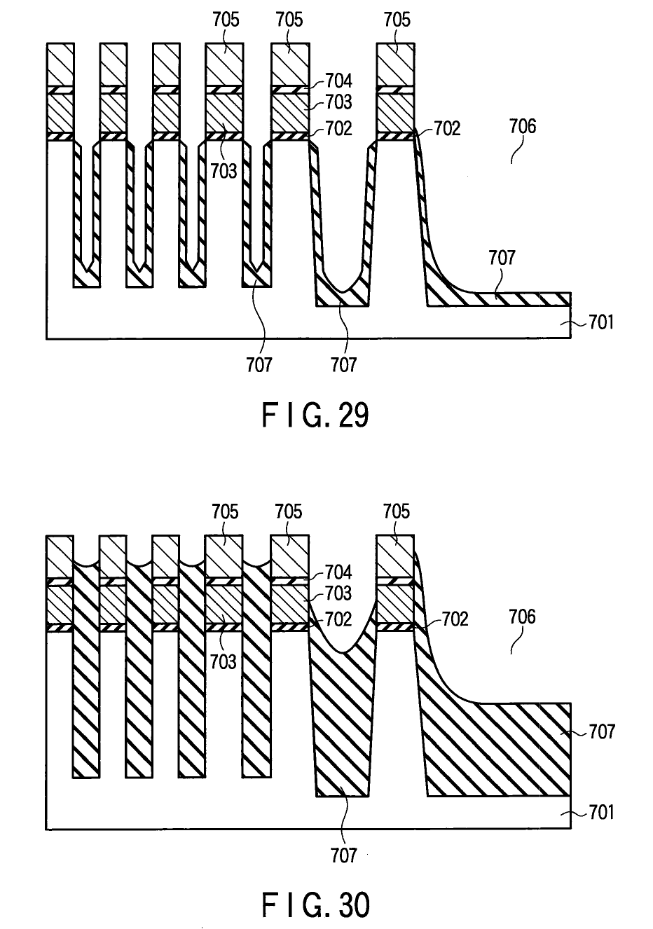

A semiconductor device and a manufacturing method thereof according to the seventh embodiment of this invention are explained with reference to FIGS. 29 to 32. This embodiment is an example applied to a flash memory having a gate dielectric film formed in advance of STI formation.

In this invention, in order to enhance the underlying material selectivity of an O₃-TEOS film, a polysilicon or amorphous silicon film or silicon germanium film is used as a CMP stopper instead of a normally used CMP stopper of a silicon nitride film series. This is because the underlying material selectivity of the O₃-TEOS film (incubation time that is time lag between CVD source gas supply and the beginning of O₃-TEOS film growth underlying material) is obtained as shown in the following table 3.

TABLE 3

film formation
temperature of the
O₃-TEOS film [° C.]

| | |
|---|---|
| 400° C. | 450° C. |
| average | average |

Incubation Time [min]

| | 30 nm/min | 23 nm/min |
|---|---|---|
| single crystalline silicon | 1.0 min | 0.6 min |
| silicon nitride film | 5.5 min | 4.8 min |
| CVD silicon oxide film (TEOS film) | 5.1 min | 4.2 min |
| non-doped polysilicon film | 8.5 min | 8.1 min |
| P-doped polysilicon film | 9.3 min | 9.1 min |
| B-doped polysilicon film | 10.1 min | 9.9 min |
| As-doped polysilicon film | 8.9 min | 8.4 min |
| non-doped amorphous silicon film | 7.3 min | 7.0 min |
| P-doped amorphous silicon film | 7.5 min | 7.2 min |
| polysilicon germanium film | 8.7 min | 8.5 min |
| P-doped polysilicon germanium film | 9.6 min | 9.2 min |

That is, since film formation on the sidewall of the CMP stopper with respect to a single crystalline silicon substrate can be suppressed by using a polysilicon or amorphous silicon film or silicon germanium film, a film can be formed in a bottom-up form. The first dielectric film having substantially no seam and formed in a bottom-up form can be formed in the STI isolation trench by using the above-mentioned CMP stopper and the low temperature O₃-TEOS condition having high underlying material selectivity. Then, the second dielectric film is formed on the first dielectric film to fill the isolation trench and thus an STI forming method in which erosion due to oxidation of the AA region is prevented can be provided. Further, according to this embodiment, since extremely small STI portions can be formed, the flash memory and logic device can be further downsized and the performance thereof can be further enhanced.

First, as shown in FIG. 29, a silicon thermal oxynitride film 702 with a thickness of 8 nm used as gate dielectric films, a P-doped polysilicon film 703 with a thickness of 60 nm used as floating gates and a silicon thermal oxide film 704 with a thickness of 10 nm obtained by exposing the surface of the P-doped polysilicon film 703 to plasma oxidation are stacked on a semiconductor substrate 701. Further, a polysilicon film 705 used as a CMP stopper is formed to a thickness of 50 nm. Then, a CVD silicon oxide film (not shown) used as a mask for reactive ion etching (RIE) is formed to a thickness of 200 nm on the entire surface of the substrate and a photoresist film (not shown) is coated and formed on the silicon oxide film.

Subsequently, the photoresist film is patterned by a normal lithography technique and the silicon oxide film is patterned by an RIE process using the photoresist film as a mask to form a hard mask. The photoresist film is removed by an etching process using a hydrogen peroxide sulfuric acid mixture and ashing. Next, the polysilicon film 705, silicon thermal oxide film 704, P-doped polysilicon film 703, silicon thermal oxynitride film 702 and semiconductor substrate 701 are sequentially patterned by an RIE process using the hard mask formed of the CVD silicon oxide film to form trenches with a depth of approximately 220 nm. Further, the residuals of a reaction byproduct in the RIE step and the CVD silicon oxide film of the hard mask are removed by hydrofluoric acid vapor. Thus, isolation trenches 706 used as STI regions are formed.

Next, as shown in FIG. 30, a first O₃-TEOS film 707 is deposited on the entire surface of the substrate to have a thickness of approximately 200 nm on the Si substrate. In this case, the film deposition temperature of the O₃-TEOS film is 400° C. and the O₃/TEOS ratio is 9.5. Under these film deposition conditions, growth of the O₃-TEOS film exhibits high underlying material dependence and almost no film deposition occurs on the polysilicon film 705, silicon thermal oxide film 704 or P-doped polysilicon film 703. Therefore, the O₃-TEOS film 707 is formed in a bottom-up shape as if it were selectively grown from the STI bottom portion.

Then, the second O₃-TEOS film 708 is formed on the O₃-TEOS film 707 to completely fill the isolation trenches 706. At this time, the film deposition temperature of the second O₃-TEOS film is 540° C. and the O₃/TEOS ratio is 3. Under these conditions, the second O₃-TEOS film 708 is formed in substantially a conformal form. However, since the isolation trench is already filled almost completely with the first O₃-TEOS film and the wide isolation trench is formed into a shape in which the taper angle is reduced and the film can be easily filled, the filling process can be performed without substantially causing any seams or voids.

Next, an anneal process is performed at a temperature of approximately 850° C. for about one hour in nitrogen to enhance the densities of the O₃-TEOS films 707, 708. Generally, for the heating process for the O₃-TEOS film, oxidation in the steam atmosphere is fatal. Therefore, in the structure in which the gate dielectric film is formed in advance of STI formation as in this embodiment, the substrate 701 and the P-doped polysilicon film 703 used as floating gates may be oxidized during the heating process of the O₃-TEOS films. As a result, the effective gate oxide film thickness is increased and a problem of a degraded reliability due to an increase in write voltage or concentration of an electric field occurs.

However, in this embodiment, since two types of deposition conditions of the O₃-TEOS films are combined, particularly, the first O₃-TEOS film is formed in a substantially bottom-up shape and occurrence of seams/voids is suppressed, the density of the O₃-TEOS film can be enhanced merely by performing an anneal process in an inert gas such as nitrogen. Therefore, STI filling can be attained without adversely affecting the characteristic of the flash memory.

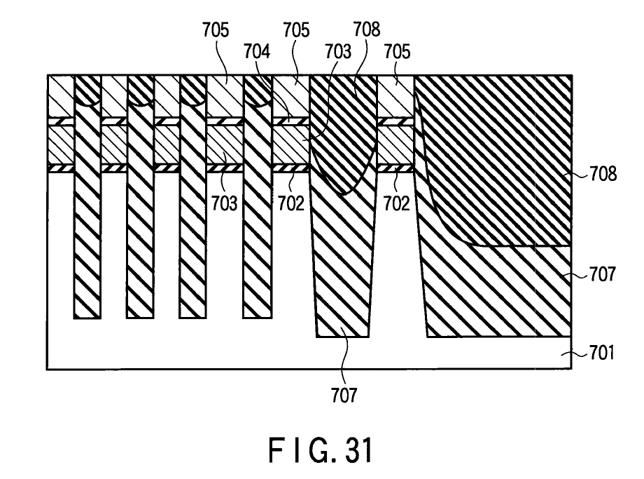

Next, when the O₃-TEOS films 707, 708 are polished with the polysilicon film 705 used as a stopper by the CMP technique and left only in the internal portions of the isolation trenches 706, the structure shown in FIG. 31 is obtained.

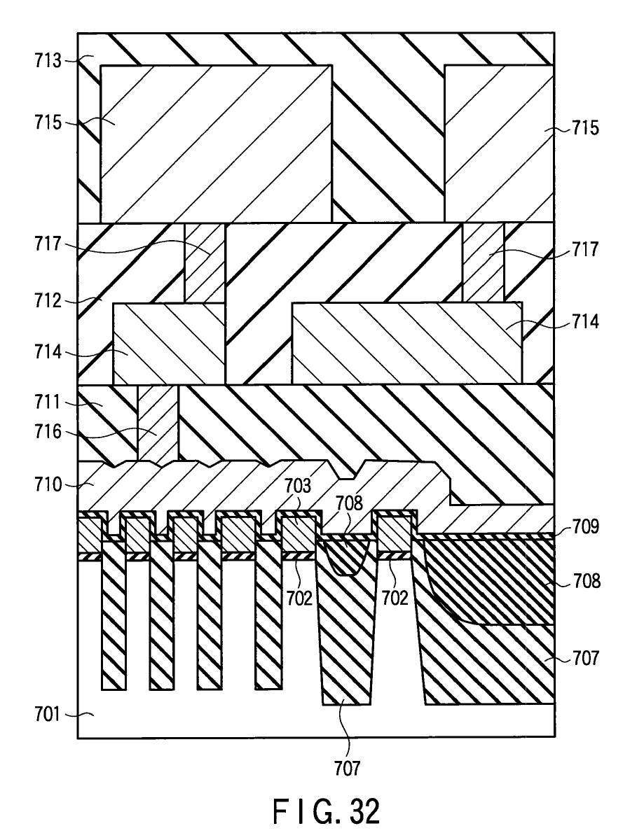

Subsequently, as shown in FIG. 32, the STI height is adjusted by reactive ion etching and then the polysilicon film 705 is removed by chemical dry etching (CDE) to from STI regions. Next, the silicon thermal oxide film 704 and the silicon oxide film on the P-doped polysilicon film 703 are removed by performing a wet-etching process using a hydrofluoric acid series. Then, an ONO film 709 used as an inter-polysilicon gate dielectric film (IPD) and a P-doped polysilicon film 710 used as control gate electrodes are formed and then the P-doped polysilicon film 710, ONO film 709 and P-doped polysilicon film 703 are sequentially patterned by a known lithography technique and RIE technique to form control gates and floating gates. In the succeeding process, inter-layer dielectric films (ILD) 711, 712, 713 are formed and interconnections 714, 715 and contact plugs 716, 717 are formed, but the detailed explanation thereof is abbreviated and only the final structure of a device is shown in FIG. 32.

With the structure and manufacturing method of this embodiment, substantially the same operation and effect as those of the above embodiments can be attained.

In this embodiment, the O₃-TEOS film having no underlying material dependence is used as the second dielectric film. However, the narrow STI portion is substantially filled after the O₃-TEOS film having high underlying material dependence and used as the first dielectric film is filled and the wide STI portion is formed with the raised bottom in a forward tapered form in which the second dielectric film can be easily filled. Therefore, the remaining portion of the isolation trench can be filled with an HDP-CVD silicon oxide film, LPCVD silicon oxide film or SOG film.

### Eighth Embodiment

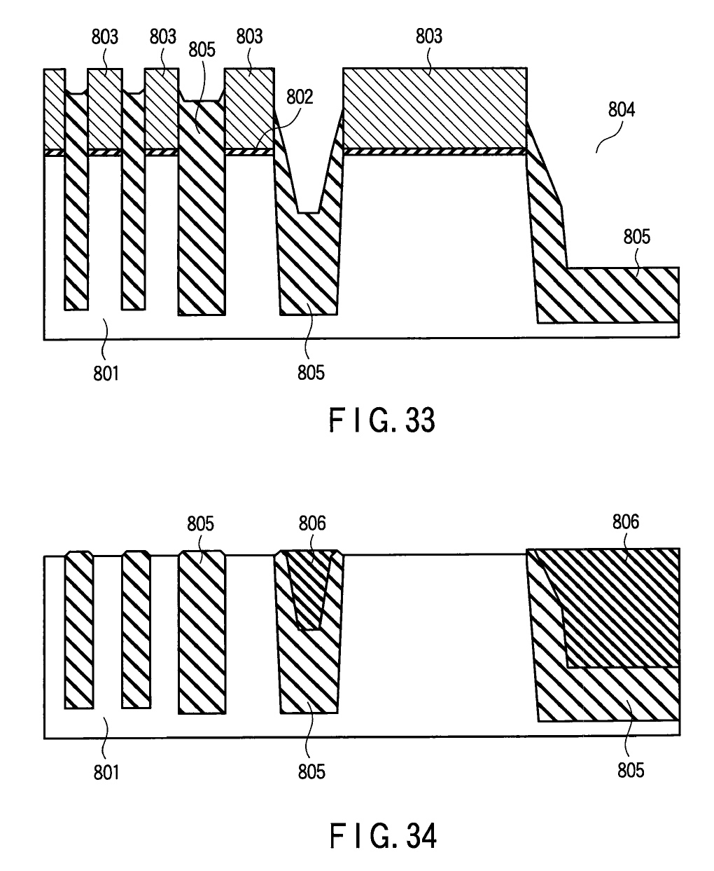

A semiconductor device and a manufacturing method thereof according to the eighth embodiment of this invention are explained with reference to FIGS. 33 to 35. This embodiment is an example of a logic device in which an STI portion is filled with an O₃-TEOS film having high undercoat dependence and an HDP-CVD silicon oxide film.

First, as shown in FIG. 33, a silicon thermal oxide film 802 with a thickness of 4 nm used as a sacrificial oxide film and a P-doped amorphous silicon film 803 with a thickness of 100 nm used as a CMP stopper are formed on a semiconductor substrate 801. Then, a CVD silicon oxide film (not shown) used as a mask for reactive ion etching (RIE) is formed on the entire surface of the substrate and a photoresist film (not shown) is coated and formed on the silicon oxide film. Next, the photoresist film is patterned by a normal lithography technique and the silicon oxide film is patterned by an RIE process using the photoresist film as a mask to form a hard mask. The photoresist film is removed by an etching process using a hydrogen peroxide sulfuric acid mixture and ashing. The silicon nitride film 803, silicon thermal oxide film 802 and semiconductor substrate 801 are sequentially patterned by an RIE process using the hard mask formed of the CVD silicon oxide film to form trenches with an etching depth of approximately 300 nm in the semiconductor substrate 801. Further, the residuals of a reaction byproduct in the RIE step and the CVD silicon oxide film are removed by performing a wet process. Thus, isolation trenches 804 used as STI regions are formed.

Next, an O₃-TEOS film 805 is deposited on the entire surface of the substrate to have a thickness of approximately 120 nm on the Si substrate. The film deposition temperature of the O₃-TEOS film is 450° C. and the O₃/TEOS ratio is 11. Under these film deposition conditions, growth of the O₃-TEOS film exhibits high underlying material dependence and almost no film formation occurs on the silicon nitride film 803 or silicon thermal oxide film 802. Therefore, the O₃-TEOS film 805 is deposited in a shape as if it were formed from the STI bottom portion in a combined method of selective growth and conformal growth.

Next, as shown in FIG. 34, an HDP-CVD silicon oxide film 806 is deposited on the entire surface of the substrate to fill the isolation trenches 804. The coverage of the HDP-CVD silicon oxide film 806 largely depends on the unfilled trench shape. However, since the internal portion of the isolation trench 804 is formed with the raised bottom in a forward tapered shape by forming the O₃-TEOS film having high underlying material dependence, the HDP-CVD silicon oxide film 806 can be relatively easily filled without causing any voids.

Subsequently, the HDP-CVD silicon oxide film 806 and O₃-TEOS film 805 are polished and left only in the isolation trenches 804 with the silicon nitride film 803 used as a stopper by the CMP technique. Further, the films are wet-etched back to adjust the height of the STI portion by using buffered hydrofluoric acid. Then, the silicon nitride film 803 is removed in hot phosphoric acid and the silicon thermal oxide film 802 is removed by a wet-etching process using a chemical of a hydrofluoric acid series to form STI regions.

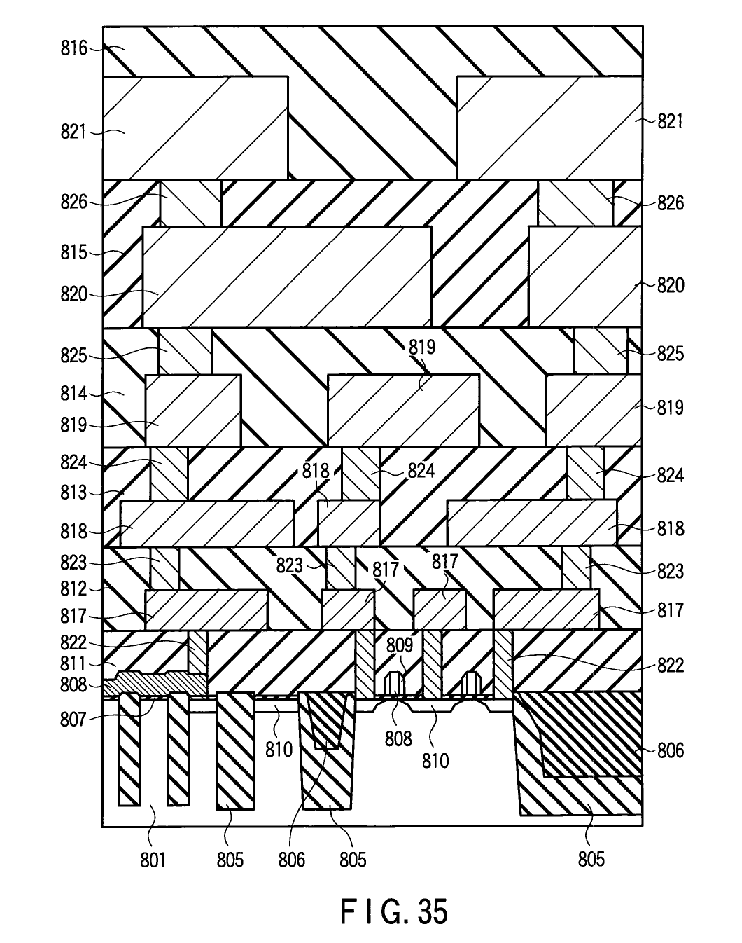

Then, as shown in FIG. 35, gate dielectric films 807, gate electrodes 808, sidewall spacers 809 and diffusion layers 810 are deposited to form transistors. In the succeeding process, inter-layer dielectric films or pre-metal dielectric films (PMD/ILD) 811, 812, 813, 814, 815, 816 are formed and interconnections 817, 818, 819, 820, 821 and contact plugs 822, 823, 824, 825, 826 are formed, but the detailed explanation thereof is abbreviated and only the final structure of a device is shown in FIG. 35.

The seventh and eighth embodiments are explained above, but the method of this invention is not limited to the combinations described in the above embodiments and the same effect can be attained by adequately combining the device, the type of the CMP stopper film (amorphous, polysilicon, non-doped, P-doped, B-doped, As-doped, silicon film, silicon-germanium film), STI filling method and the like.

As described above, in the manufacturing method of the flash memory according to the first embodiment of this invention, an STI region is completely filled by forming a stacked film of a gate dielectric film and electrode film to form memory cells of a flash memory on a semiconductor substrate, processing the stacked film by reactive ion etching, forming an isolation trench used as a shallow trench isolation (STI) region to expose the substrate silicon surface, filling an O₃-TEOS film exhibiting underlying material selectivity during the film deposition as the first filling dielectric film, and completely filling the isolation trench with the second filling dielectric film.

Further, as preferable embodiments of this invention, the following embodiments are given.

(a) The second filling dielectric film is an O₃-TEOS film that does not exhibit underlying material selectivity during the film deposition.

(b) The second filling dielectric film is an SOG film.

Further, in the flash memory according to the second embodiment of this invention, at least part of the shallow trench isolation region is filled with two types of dielectric films; particularly, a narrow STI portion of the cell portion is filled with an O₃-TEOS film and a wide STI portion in the peripheral circuit portion is filled with an O₃-TEOS film formed thick in the STI bottom portion, particularly, in the STI bottom corner portion and an SOG film formed on the O₃-TEOS film.

In the flash memory according to the third embodiment of this invention, at least part of the shallow trench isolation region is filled with two types of dielectric films; particularly, a narrow STI portion of the cell portion is filled with an O₃-TEOS film formed on the STI sidewall and an SOG film filled in the STI central portion in the manner that the top of the SOG film set lower than the top of the O₃-TEOS film and a wide STI portion in the peripheral circuit portion is filled with an O₃-TEOS film formed thick in the STI bottom portion, particularly, in the STI bottom corner portion and an SOG film formed on the O₃-TEOS film.

According to the above manufacturing method and structure, the following effects can be attained.

(1) An O₃-TEOS film can be formed without causing almost any seams or voids by forming O₃-TEOS on the isolation trench exposing Si surface under a condition with high underlying material selectivity.

(2) The O₃-TEOS film can be annealed in an atmosphere of inert gas such as nitrogen since almost no seam or void occurs under a condition with high underlying material selectivity, and therefore, a degradation of the flash memory characteristic due to substrate oxidation does not occur.

(3) It is difficult to form an O₃-TEOS film thick under a condition with high underlying material selectivity, but the process time required for forming an O₃-TEOS film in a condition with high underlying material selectivity can be reduced by using a second dielectric film in combination therewith.

Further, since the isolation trench can be formed into a shape that can be easily filled by using the O₃-TEOS film with high underlying material selectivity according to the manufacturing method (a), an O₃-TEOS film can be formed without substantially causing any seam or void.

According to the manufacturing method (b), the surface of the O₃-TEOS film with high underlying material selectivity tends to become rough if it is formed thick, but an STI portion can be filled without substantially causing any seam or void by using an SOG film in combination therewith. Therefore, a narrow STI portion can be completely filled by forming the O₃-TEOS film thick.

Further, according to the structures of the second and third embodiments, the following effects can be attained.

(4) Since the coating film thickness of the SOG film can be reduced, suppression of occurrence of crystalline defects, film cracking and film peeling due to a reduction in the film stress can be attained.

(5) Since the coating film thickness of the SOG film can be reduced, occurrence of fixed charges due to impurities in the SOG film and a degrading in the transistor characteristic caused by fixed charges can be suppressed.

(6) Concentration of stress in the STI bottom corner portion can be reduced by forming an O₃-TEOS film thick in the STI bottom portion, particularly, in the STI bottom corner portion, and thus the effect of reinforcement of AA can be attained.

According to the structure of the third embodiment, since the STI central portion of the cell portion is formed into a concave shape and the control gate electrode of the flash memory enters part of the concave portion, electrical interference between adjacent cells can be suppressed.

The manufacturing method of the semiconductor device according to the fourth embodiment involves forming an STI region by forming an isolation trench used as a shallow trench isolation (STI) region in the semiconductor substrate, filling an O₃-TEOS film exhibiting underlying material selectivity during the film deposition as the first filling dielectric film on the substrate, oxidizing the internal surface of the isolation trench over the first dielectric film, and forming the second dielectric film on the first dielectric film to completely fill the isolation trench.

Further, as preferable embodiments of this invention, the following examples are given.

(c) The second filling dielectric film is one of an SOG film, HDP-CVD silicon oxide film and O₃-TEOS film exhibiting no underlying material selectivity during the film deposition.

(d) The processing size of an active area is controlled in a step of oxidizing the internal surface of the trench.

With the above manufacturing method, the following effects can be attained.

(7) Oxidation caused by lateral diffusion of an oxidizing agent can be suppressed by oxidizing the internal surface of the isolation trench over the first dielectric film. This is because the oxidizing agent cannot reach the internal surface of the isolation trench if it hardly diffuse through the first dielectric film, therefore it becomes difficult for the oxidizing agent to diffuse further deeply. That is, in the case of a flash memory in which the gate dielectric film is formed in advance of STI formation, an oxidizing agent diffuses between the floating gate and the tunnel oxide film to increase the thickness of the tunnel oxide film, and a degrading the write characteristic can be suppressed.

(8) Oxidation caused by lateral diffusion of an oxidizing agent can be suppressed by oxidizing the internal surface of the isolation trench over the first dielectric film. This is because the oxidizing agent cannot reach the internal surface of the isolation trench if it does not diffuse within the first dielectric film, thus making it difficult for the oxidizing agent to diffuse further deeply. That is, in the case of a logic device in which the STI portion is formed in advance, an oxidizing agent is diffused between the silicon nitride film of the CMP stopper and the substrate, and deformation of the active area can be suppressed.

According to the manufacturing method (c), since the internal surface of the isolation trench can be formed into a tapered shape that permits a film to be easily filled by use of an O₃-TEOS film exhibiting high underlying material selectivity, it becomes possible to fill a dielectric film used in the conventional STI filling process without substantially causing any seams or voids.

According to the manufacturing method (d), since oxidation caused by lateral diffusion of an oxidizing agent can be suppressed by oxidizing the internal surface of the isolation trench over the first dielectric film, only the innermost surface of the isolation trench can be oxidized. Therefore, the active area can be made narrower without deforming the active area, for example, rounding the upper portion of the active area. Particularly, a high degree of strength of the active area cannot be attained in a device with the minimum half pitch of 40 nm or less by use of the conventional lithography technique and the processing technique by reactive ion etching, and a problem of collapse of patterns and peeling of patterns tends to occur. However, in the method of this invention, since the active area can be narrowed by oxidation after the relatively thick active area is further reinforced by use of the first dielectric film, a highly downsized active area can be formed.

The manufacturing method of the semiconductor device according to the fifth embodiment of this invention involves forming an STI region by forming a doped or non-doped amorphous silicon film, polysilicon film or silicon germanium film used as a CMP stopper on the semiconductor substrate, forming an isolation trench used as a shallow trench isolation (STI) portion, filling an O₃-TEOS film exhibiting undercoat selectivity at the film formation time as the first filling dielectric film on the substrate, and forming the second dielectric film on the first dielectric film to completely fill the isolation trench.

Further, as preferable embodiments of this invention, the following examples are given.

(e) A step of forming a doped or non-doped amorphous silicon film, polysilicon film or silicon germanium film used as a CMP stopper over a conductive film acting as the gate electrode of a semiconductor device in which the gate dielectric film is formed in advance of STI formation with a dielectric film inserted therebetween is provided.

(f) The doped or non-doped amorphous silicon film, polysilicon film or silicon germanium film used as the CMP stopper is removed by dry etching.

With the above manufacturing method, the following effects can be attained.

(9) The underlying material selectivity of the O₃-TEOS film can be enhanced by using a doped or non-doped amorphous silicon film, polysilicon film or silicon germanium film used as a CMP stopper instead of a silicon nitride film that is generally used. Therefore, O₃-TEOS film grows only in the trench of the silicon substrate at the early stage of film deposition and film deposition can be performed in a completely bottom-up form without causing any seam after the trench of the substrate is filled. As a result, the STI central portion is hardly etched even if the STI top is exposed to wet-etching and thus the gate electrodes will not be short-circuited.

According to the manufacturing method (e), since a portion lying under the CMP stopper film generally becomes a conductive film such as a polysilicon film in a device such as a flash memory in which the gate is formed in advance of STI formation, it becomes difficult to selectively remove the CMP stopper if the doped or non-doped amorphous silicon film, polysilicon film or silicon germanium film is used as the CMP stopper. On the other hand, if a CMP stopper film is formed above the conductive film with a dielectric film such as a silicon oxide film inserted therebetween, the CMP stopper film can be easily selectively separated.

According to the manufacturing method (f), it becomes difficult to selectively remove the CMP stopper by wet etching, for example, remove a silicon nitride film in hot phosphoric acid if the doped or non-doped amorphous silicon film, polysilicon film or silicon germanium film is used as the CMP stopper. However, selective removal of the CMP stopper with respect to a silicon oxide film can be made by using dry etching such as reactive ion etching or chemical dry etching (CDE). Since the doped or non-doped amorphous silicon film, polysilicon film or silicon germanium film is originally widely used as the gate electrode of a transistor, highly selective dry-etching with respect to the silicon oxide film is developed as a gate electrode patterning technique, and selective etching of the CMP stopper film with high precision can be performed.

As described above, according to one aspect of this invention, a semiconductor device having a highly reliable element isolation region of a preferable characteristic and a manufacturing method thereof are obtained.

### Ninth Embodiment

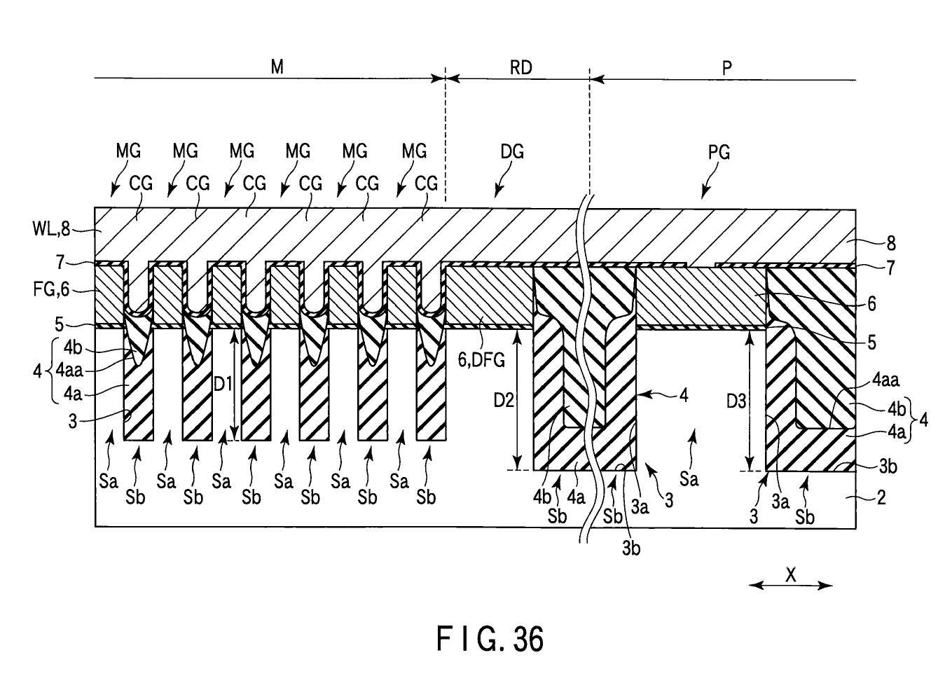

Next, a NAND flash memory according to the ninth embodiment of this invention is explained with reference to FIGS. 36 to 45.

FIG. 36 schematically shows a cross section of the flash memory according to the ninth embodiment of this invention. As shown in FIG. 36, a peripheral circuit region P is provided in a position separated from a memory cell region M in an X direction and a dummy region RD is provided between the peripheral circuit region P and the memory cell region M. The dummy region RD is provided in a boundary portion between the memory cell region M and the peripheral circuit region P to securely attain a regular pattern repetition.

A plurality of element isolation trenches 3 separated in the X direction are formed to extend in a Y direction intersecting at right angles to the X direction in the surface layer of a semiconductor substrate (for example, a p-type silicon substrate) 2. In the memory cell region M, element isolation trenches 3 separated at preset intervals in the X direction are formed in the surface layer of the semiconductor substrate 2. Thus, a plurality of active areas Sa are divided from one another. On the respective active areas Sa, gate dielectric films 5 and floating gate electrodes FG are stacked. For example, the gate dielectric film 5 is formed of a silicon oxide film and the floating gate electrode FG is formed of a polysilicon layer 6.

Further, in each element isolation trench 3, an element isolation dielectric film 4 is filled. The element isolation dielectric film 4 is configured by a stacked structure of an O₃-TEOS film 4a formed along the internal surface of the element isolation trench 3, and a polysilazane film 4b coated over the upper surface of the O₃-TEOS film 4a. The top of the element isolation dielectric film 4 is above the gate dielectric film 5 level and is set lower than the top of the floating gate FG.

In the memory cell region M, the O₃-TEOS film 4a is formed so that the upper surface thereof is formed in a downwardly curved form and the central portion in the X direction is formed as an inner lowest portion 4aa acting as the deepest portion. Further, each O₃-TEOS film 4a is formed on the lower side surfaces of the adjacent polysilicon layers 6 and on the side surfaces of the adjacent gate dielectric films 5 to entirely cover the inner surface of each element isolation trench 3 formed in the semiconductor substrate 2. In the memory cell region M, the inner lowermost portions 4aa of the O₃-TEOS films 4a filled in the element isolation trenches 3 are equally formed to the preset depth.

In the memory cell region M, the polysilazane film 4b is formed along the curved upper surface of the O₃-TEOS film 4a and the upper surface thereof is set lower than the upper surface of the polysilicon layer 6 and set higher than the lower surface thereof. The upper surface of the polysilazane film 4b is formed in a curved form (U-shaped form). In the memory cell region M, the side surface of the polysilicon layer 6, the side surface of the gate dielectric film 5 with displacement.

A inter-poly-silicon gate dielectric (IPD) film 7 is formed on the upper surfaces of the element isolation dielectric films 4 and the upper side surfaces and upper surfaces of the polysilicon layers 6, and formed to cover the polysilicon layers 6 (floating gate electrodes FG) separated in the X direction. For example, IPD film 7 is an oxide-nitride-oxide (ONO) film. As a material of the IPD film 7, a nitride-oxide-nitride-oxide-nitride (NONON) film or a film containing alumina may be formed instead of the ONO film.

Word lines WL are formed on the IPD film 7. For example, the word line WL is formed of a polysilicon film and a conductive layer 8 obtained by silicidation the upper portion thereof with a metal such as tungsten to connect control gate electrodes CG configuring memory cell gate electrodes MG. As a result, in the memory cell region M, the floating gate electrode FG, IPD film 7 and control gate electrode CG are stacked on each active area with the gate dielectric film 5 inserted therebetween and each memory cell gate electrode MG is configured by the stacked structure FG, 7, CG.

In the dummy region RD located directly adjacent to the memory cell region M in the X direction, a dummy stacked gate electrode DG is formed. The dummy stacked gate electrode DG is formed by stacking the polysilicon layer 6, IPD film 7 and conductive layer 8 (word line WL) on the active area Sa with the gate dielectric film 5 inserted therebetween. Therefore, in the dummy region RD, a dummy floating gate electrode DFG is formed of the same material as that of the polysilicon layer 6 that configures the gate electrode MG in the memory cell region M on the semiconductor substrate 2 with the gate dielectric film 5 inserted therebetween.

The dummy stacked gate electrode DG is arranged in the X direction, which is the arrangement direction of the memory cell gate electrodes MG. The width of the active area Sa of the dummy stacked gate electrode DG in the X direction is set wider than the width of the active area Sa of the memory cell gate electrodes MG and set smaller than the width of the active area Sa in the peripheral circuit region P.

An element isolation trench 3 with depth D2 deeper than depth D1 of the element isolation trench 3 in the memory cell region M is formed in a portion directly adjacent to the dummy floating gate electrode DFG in the X direction and an element isolation dielectric film 4 is filled in the element isolation trench 3 with the depth D2. Like the element isolation dielectric film 4 in the memory cell region M, the above element isolation dielectric film 4 is formed of a stacked structure of an O₃-TEOS film 4a and polysilazane film 4b.

The width of the element isolation dielectric film 4 of the dummy region RD in the X direction is set wider than the width of the element isolation dielectric film 4 in the memory cell region M in the X direction and set narrower than the width of the element isolation dielectric film 4 in the peripheral circuit region P although not shown in the drawing. Thus, a regular pattern repetition between the structure in the memory cell region M and the structure in the dummy region RD is securely attained.

In the peripheral circuit region P, a gate electrode PG is formed. The gate electrode PG is formed by stacking the polysilicon layer 6, IPD film 7 and conductive layer 8 (word line WL) on the active area Sa with the gate dielectric film 5 inserted therebetween. An opening is formed in the central portion of the gate-gate dielectric film 7 to structurally and electrically connect the polysilicon layer 6 and conductive layer 8 with each other.

In the peripheral circuit region P, the element isolation trench 3 having depth D3 deeper than the depth D1 is formed directly adjacent to the gate electrode PG in the X direction, and an element isolation dielectric film 4 is similarly filled in the element isolation trench 3 of the depth D3. Like the element isolation dielectric film 4 in the memory cell region M, the above element isolation dielectric film 4 is formed of a stacked structure of an O₃-TEOS film 4a and polysilazane film 4b.

The O₃-TEOS films 4a are formed in the element isolation trenches 3 of the depths D2 and D3 so that a film formed beside the side portion of the gate dielectric film 5 will have substantially the same film thickness as the film thickness of a film formed on the side wall 3a of the element isolation trench 3 in the semiconductor substrate 2. Further, the film is so formed as to become gradually thinner in an upward direction from the side portion of the gate dielectric film 5.

The O₃-TEOS films 4a are formed in the element isolation trenches 3 of the depths D2 and D3 with the inner lower end portions 4aa thereof set in a deeper position than the inner lower end portion 4aa of the O₃-TEOS film 4a in the memory cell region M. Further, the O₃-TEOS films 4a are formed in the element isolation trenches 3 of the depths D2 and D3 with the ratio of the thicknesses of the film portions formed on the side wall 3a and bottom portion 3b of the element isolation trench 3 set to 1:1.5 or lower and the thickness of the film portion on the bottom portion 3b of the element isolation trench 3 set equal to or thicker than preset film thickness (50 nm).

The polysilazane film 4b is formed along the curved upper surface of the O₃-TEOS film 4a in each of the element isolation trenches 3 of the depths D2 and D3. The height of the top of the polysilazane film 4b is set substantially the same as the height of the top of the polysilicon layer 6.

A manufacturing method of the above structure is explained. The explanation is specifically centered on the characteristic manufacturing step in this embodiment, but the manufacturing steps explained below may be exchanged as required, a general step or a step of forming a different region (not shown) may be additionally provided and a step may be omitted as required.

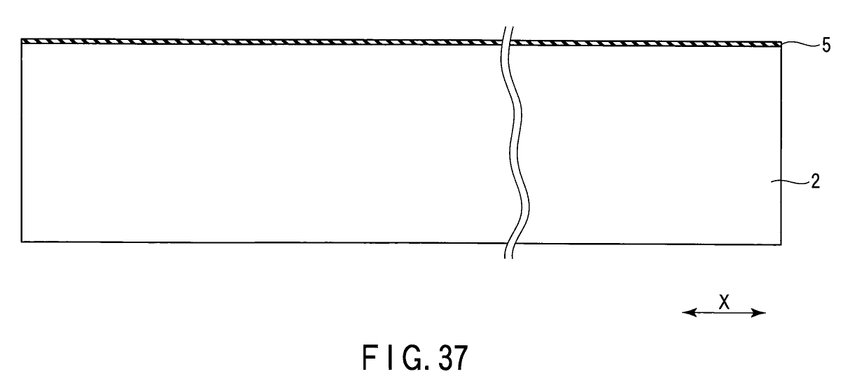

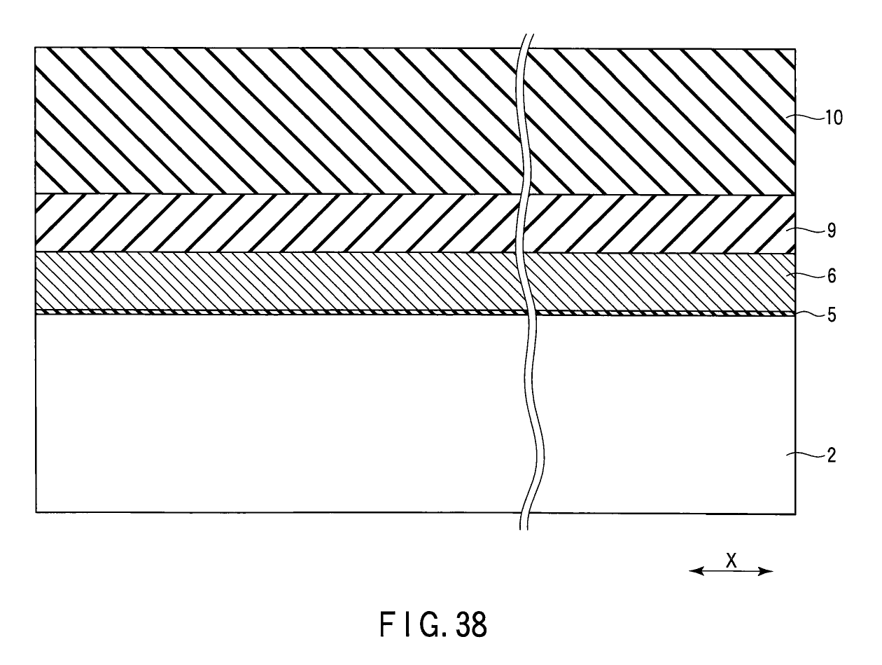

First, as shown in FIG. 37, a well region (not shown) is formed on a semiconductor substrate 2 and ion-implantation is performed to form channel regions. Then, an oxide film acting as a gate dielectric film 5 is formed to a preset film thickness (for example, 8 nm) on the semiconductor substrate 2 by a thermal oxidation method. Next, as shown in FIG. 38, amorphous silicon having an impurity such as phosphorous doped therein is deposited and formed to a preset film thickness (for example, 95 nm) on the gate dielectric film 5 to form an amorphous silicon film used as parts of floating gate electrodes FG and gate electrodes PG by the CVD method. Subsequently, a silicon nitride film 9 and silicon oxide film 10 are sequentially deposited to respective film thicknesses (for example, 70 nm and 300 nm) by the CVD method.

Amorphous silicon is converted to polysilicon by an annealing process, performed later to form a polysilicon layer 6. The silicon nitride film 9 acts as a CMP stopper, and the silicon oxide film 10 is formed as a mask in the reactive ion etching (RIE) method.

Next, a photoresist film (not shown) is coated and then patterned by a known lithography technique. Then, as shown in FIG. 39, the silicon oxide film 10 is patterned by the RIE method with the patterned photoresist film used as a mask to form a hard mask. In this case, the width W1 of the element isolation trench 3 in the memory cell region M is set smaller than the width W2 of the element isolation trench 3 in the peripheral circuit region P. Subsequently, the photoresist film is removed by ashing and an etching process using a hydrogen peroxide sulfuric acid mixture.

Next, the silicon nitride film 9, polysilicon layer 6, gate dielectric film 5 and the upper portion of the semiconductor substrate 2 are sequentially patterned with the patterned silicon oxide film 10 used as a hard mask by the RIE method to form element isolation trenches 3. At this time, the depths D2, D3 (for example, 250 nm) of the element isolation trenches 3 in the dummy region RD and peripheral circuit region P are made smaller than the depth D1 of the element isolation trench 3 in the memory cell region M. Then, the residual of a reaction byproduct in the RIE step is removed by dilute hydrofluoric acid.

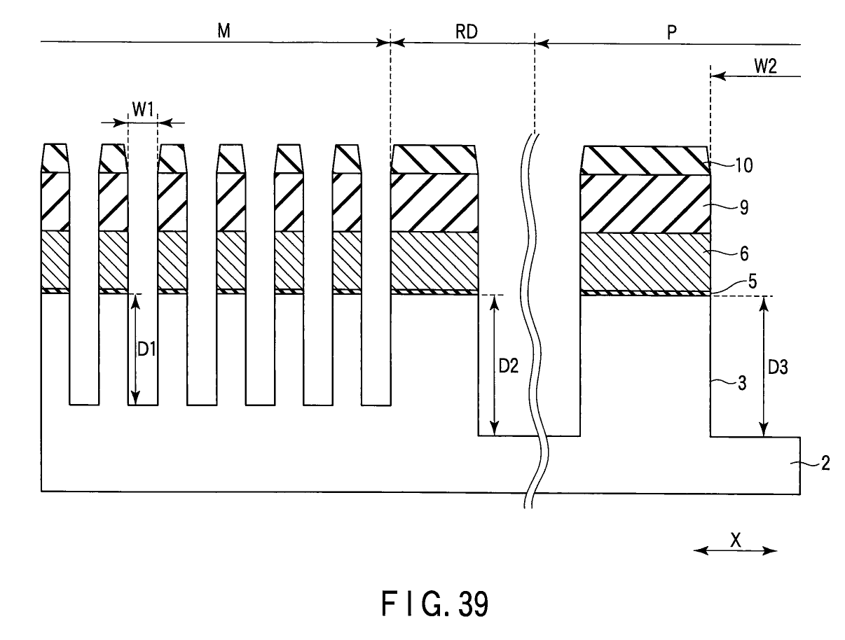

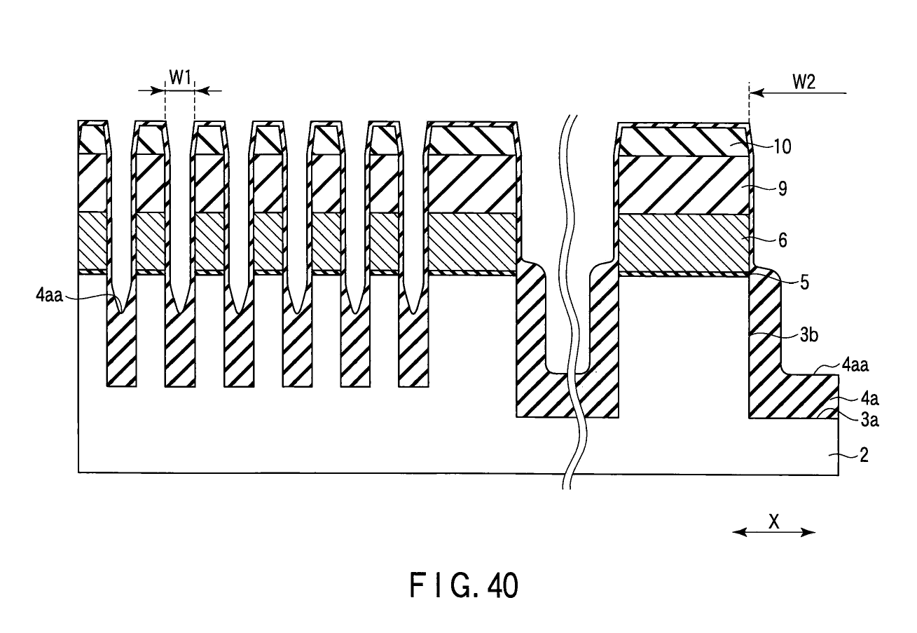

Next, as shown in FIG. 40, an O₃-TEOS film 4a is deposited on the entire surface of the resultant semiconductor structure on a condition that it is formed to a preset film thickness (for example, 80 nm) on TP while pure water is being introduced in a vapor state into a process chamber. For example, it is preferable to set the film formation temperature of the O₃-TEOS film 4a to 480° C., set the O₃ flow rate to 20 slm, set the TEOS flow rate to 4 gm or 2 gm and set the pure water flow rate to 8 gm.

Since an O₃-TEOS film having high underlying material selectivity can be formed at relatively high temperatures by introducing pure water, an O₃-TEOS film of good quality and of less impurity can be deposited. Thus, the O₃-TEOS film 4a can be deposited in the peripheral circuit region P so that the ratio of the film thicknesses of the film portions formed along the sidewall 3a and bottom portion 3b of the element isolation trench 3 will be set to equal to or less than 1:1.5 (1.1 to 1.5) and the thickness of the film on the bottom portion 3b of the element isolation trench 3 may be set equal to or thicker than 50 nm.

An ethyl group present in TEOS in a vapor phase can be eliminated by hydrolysis by introducing pure water as vapor into the process chamber, and the film density thereof can be enhanced in comparison with that of a conventionally known O₃-TEOS film by performing dehydration after it has reached the surface of the semiconductor substrate 2. Further, the incubation time of growth on the polysilicon layer 6, silicon nitride film 9 and silicon oxide film 10 can be made longer than that of growth of a conventionally known O₃-TEOS film to form a film having underlying material selectivity by setting the temperature at 480° C. and introducing pure water. Therefore, a filling film at the early stage of deposition is formed as if it were selectively grown into a bottom-up form from the bottom portion 3b of the element isolation trench 3.

After completion of growth, the O₃-TEOS film 4a is formed along the internal surface of the element isolation trench 3, the side surfaces of the gate dielectric film 5, the side surfaces of the polysilicon layer 6, the side surfaces of the silicon nitride film 9 and the side surfaces and upper surface of the silicon oxide film 10. Particularly, the film thickness of the O₃-TEOS film 4a is set with the film thickness thereof on the side portion of the gate dielectric film 5 and on the lower portion of the side portion set thicker than the film thickness thereof on the upper side surface of the polysilicon layer 6. In this case, openings are maintained in parts of the upper portions of the element isolation trenches 3 with a narrow width W1 and wide width W2 in the peripheral circuit region P and memory cell region M.

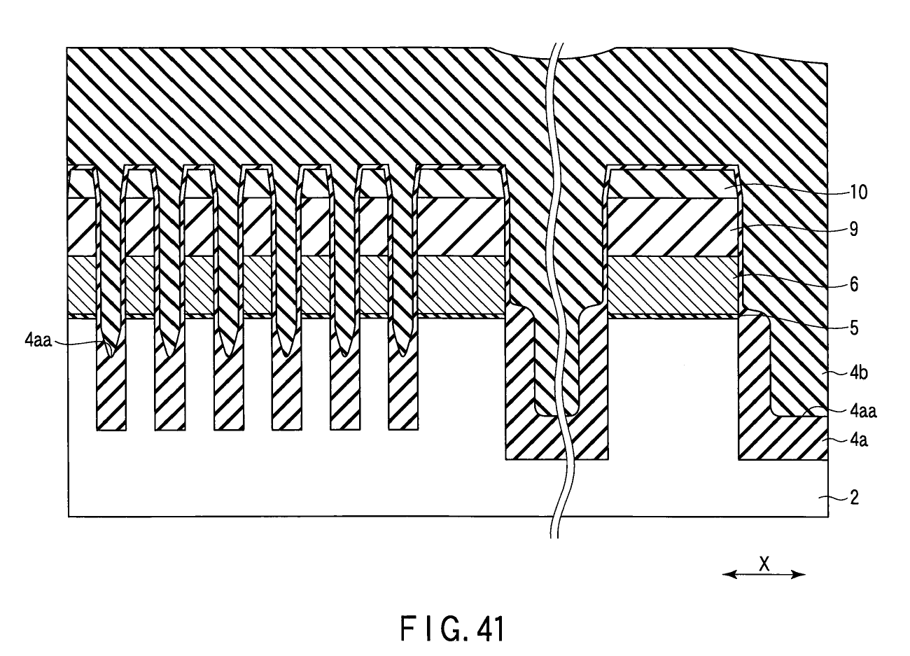

Next, an anneal process is performed in an N₂ atmosphere at 850° C. for about 30 minutes to enhance the density of the O₃-TEOS film 4a. Then, as shown in FIG. 41, a polysilazane film 4b is coated on the entire surface of the semiconductor substrate 2 to fill the element isolation trenches 3 that are partly opened. The film formation method of the polysilazane film 4b is performed as follows. A perhydropolysilazane [(SiH₂NH)ₙ] whose mean molecular weight is 2000 to 6000 is dissolved into xylene, dibutylether and the like to form a perhydropolysilazane solution and the perhydropolysilazane solution is coated on the surface of the semiconductor substrate 2 by a spin coating method.

For example, the conditions of the spin coating method are a semiconductor substrate 2 rotation speed of 1000 rpm, a rotation time of 30 seconds, a perhydropolysilazane solution drop amount of 2 cc, with a target coating film thickness immediately after baking of 470 nm. Then, the semiconductor substrate 2 on which the solution is coated is heated to 150° C. on a hot plate and baked in an inert gas atmosphere for 3 minutes to evaporate a solvent in the perhydropolysilazane solution. In this state, carbon or hydro-carbon caused by the solvent remains in the coating film as an impurity at approximately several % to several ten % and the state of the perhydropolysilazane film is set close to the state of a silicon nitride film of low density containing a residual solvent.

Nitrogen in the polysilazane film 4b is separated and oxygen is taken in place of nitrogen by oxidizing the film in a low-pressure vapor atmosphere at 300° C. Thus, the polysilazane film 4b is modified into a silicon oxide film. Then, the density of the polysilazane film 4b is enhanced by performing an anneal process in a nitrogen (N₂) atmosphere of 850° C. for one hour. Since the polysilazane film 4b contracts due to the anneal process after coating of polysilazane, tensile stress occurs in the element isolation trench 3.

The tensile stress becomes stronger as the polysilazane amount in the element isolation trench 3 becomes larger, and vice versa. In this embodiment, since the O₃-TEOS film 4a is formed along the internal surface of the element isolation trench 3, the bottom-raising amount of the bottom portion 3b of the element isolation trench 3 becomes larger than that of a high temperature oxide (HTO) film, for example, and the polysilazane amount becomes smaller. As a result, the tensile stress becomes smaller and occurrence of crystalline defects due to dislocation can be prevented.

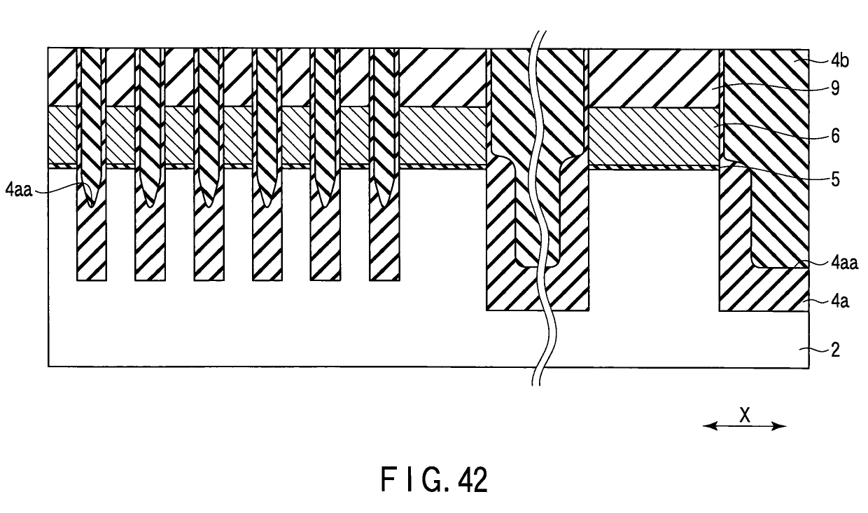

Next, as shown in FIG. 42, the coated polysilazane film 4b, O₃-TEOS film 4a and silicon oxide film 10 are polished by the chemical mechanical polishing (CMP) method using the silicon nitride film 9 as a stopper to leave the polysilazane film 4b and O₃-TEOS film 4a in the element isolation trench 3.

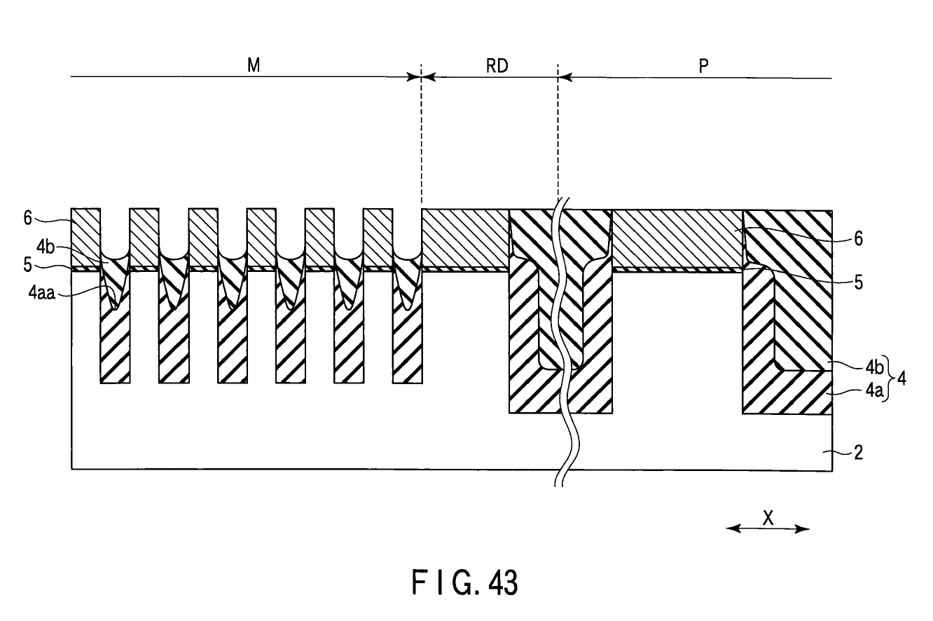

Then, as shown in FIG. 43, a mask pattern (not shown) is formed in the dummy region RD and peripheral circuit region P. Further, the upper portion of the polysilazane film 4b and the upper portion of the O₃-TEOS film 4a in the memory cell region M are etched back downwardly from the upper surface of the silicon nitride film 9 by preset film thickness (for example, 90 nm) by the RIE method and the mask pattern is removed.

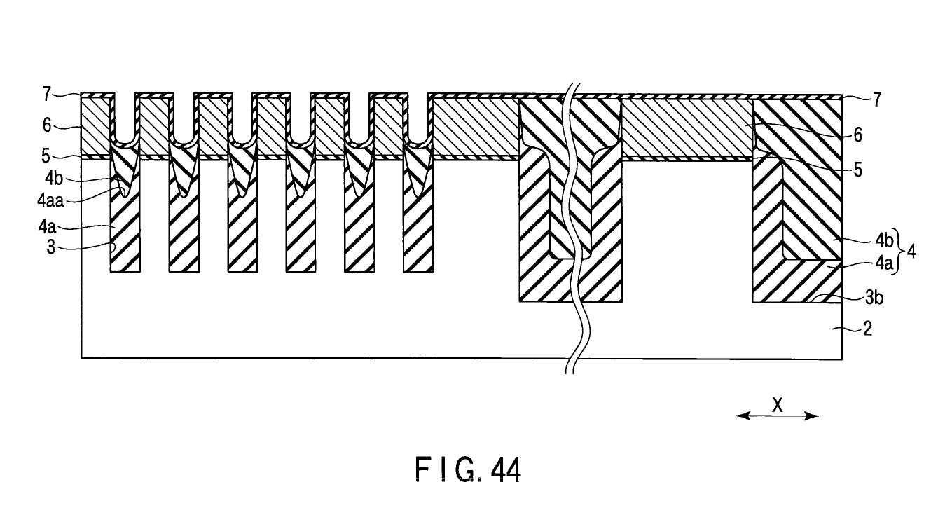

Next, as shown in FIG. 44, the silicon nitride film 9 is removed by use of hot phosphoric acid and an IPD film 7 formed of an ONO film is formed by an LP-CVD method. Then, as shown in FIG. 36, a conductive layer 8 is formed on the IPD film 7. When the conductive layer 8 is formed, phosphorous doped amorphous silicon is deposited and the upper portion of the deposited film is silicided by use of a metal such as tungsten to form word lines WL. Further, when amorphous silicon of the conductive layer 8 for the gate electrodes PG in the peripheral circuit region P is formed, thin amorphous silicon is deposited on the gate dielectric film 7, an opening is formed in the central portion of the gate-gate dielectric film 7 in the peripheral circuit region P and then amorphous silicon is further deposited.

Subsequently, the floating gate electrode FG is divided into plural portions in the Y direction by dividing the stacked film in a direction perpendicular to the drawing sheet along the X direction by performing an anisotropic etching process. Then, ions used for formation of sources and drains are implanted into the surface layer of the semiconductor substrate 2 via the divided regions, and inter-layer dielectric films (not shown) are filled in portions between the gate electrodes MG, between the gate electrodes MG and SG and a surrounding portion of the gate electrode PG as required. After this, bit line contacts CB, source line contacts CS and the like are formed and the structure of bit lines BL is formed on the upper layer, but the detailed explanation thereof is not related to the feature of this embodiment, and therefore, the explanation for the manufacturing process is abbreviated.

According to the ninth embodiment, the element isolation trenches 3 are formed in the semiconductor substrate 2, the O₃-TEOS films 4a whose upper portions are partly opened are formed on the internal surfaces of the element isolation trenches 3 and the polysilazane films 4b are formed on the O₃-TEOS films 4a. Therefore, the amount of the polysilazane film 4b formed in the element isolation trench 3 can be reduced in comparison with the conventional case, tensile stress caused by film shrinkage can be made small and occurrence of crystalline defects due to dislocation can be suppressed. In addition, diffusion of carbon from the polysilazane film 4b can be prevented.

In the memory cell region M, since the hybrid structure of the O₃-TEOS films 4a and polysilazane films 4b is applied, no void is formed in the element isolation dielectric film 4. Therefore, a variation in the parasitic capacitance between the constituents of the adjacent memory cell gate electrodes MG can be reduced and the write voltage and read voltage of each memory cell transistor Trm can be stabilized.

The O₃-TEOS films 4a are formed in the peripheral circuit region P having the element isolation trenches 3 of a width W2 wider than the width W1 of the element isolation trenches 3 in the memory cell region M. Therefore, tensile stress caused by film shrinkage, particularly, in the peripheral circuit region P can be reduced and occurrence of crystalline defects due to dislocation can be prevented.

The O₃-TEOS film 4a is formed on the internal surface of the element isolation trench 3 in the peripheral circuit region P with the ratio of the film thicknesses of the film portions respectively formed on the sidewall 3a and bottom portion 3b of the element isolation trench 3 set equal to or lower than 1:1.5 and the film thickness of the film portion on the bottom portion 3b of the element isolation trench 3 is set equal to or thicker than a preset film thickness (50 nm). Therefore, the tensile stress can be more adequately reduced and occurrence of crystalline defects due to dislocation can be prevented.

Even if the O₃-TEOS film 4a is formed in the element isolation trench 3, the film thickness of the film portion on the bottom portion 3b of the element isolation trench 3 having the large width W2 in the peripheral circuit region P can be set sufficiently large while a space reaching the upper opening portion of the element isolation trench 3 in the memory cell region M having the narrow width W1 is securely attained.

### Tenth Embodiment

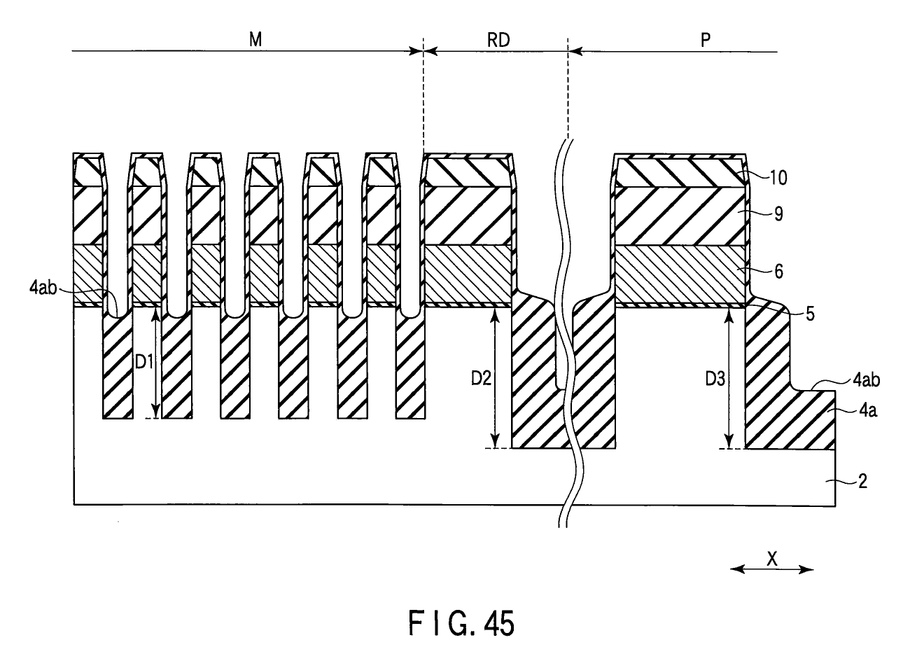

FIG. 45 shows a tenth embodiment of this invention, which is different from the ninth embodiment in that the film formation condition of the O₃-TEOS film is changed. Portions that are the same as those of the ninth embodiment are denoted by the same symbols, the explanation thereof is omitted and only different portions are explained below.

FIG. 45 is a schematic cross-sectional view showing the manufacturing step instead of the relating manufacturing step of the ninth embodiment depicted as FIG. 40. As shown in FIG. 45, in the tenth embodiment, an internal lower end portion 4ab is used instead of the internal lower end portion 4aa of the O₃-TEOS film 4a in the ninth embodiment. In the memory cell region M, the O₃-TEOS film 4a is formed to have a smoother upper surface with the curvature of the surface of the internal lower end portion 4ab set lower than the curvature of the surface of the internal lower end portion 4aa in the former embodiment.

In the memory cell region M, dummy region RD and peripheral circuit region P, the internal lower end portions 4ab are formed to be set closer to the upper surface side of the semiconductor substrate 2 in comparison with the internal lower end portions 4aa deeply formed in the former embodiment. Therefore, the amount of O₃-TEOS film 4a filled in the element isolation trench 3 becomes larger in comparison with the case of the former embodiment. Thus, even if the polysilazane film 4b is formed on the O₃-TEOS film 4a, the amount of polysilazane in the element isolation trench 3 that lies lower than the upper surface of the semiconductor substrate 2 can be reduced.

In the ninth embodiment, the film formation temperature is set at 480° C. as the film formation condition of the O₃-TEOS film 4a, but in the tenth embodiment, the film formation is performed at 300° C., which is lower than the above film formation temperature. The other film formation conditions are adjusted such that the O₃ flow rate is 27 slm, the TEOS flow rate is 0.6 gm and the pure water flow rate is 8 gm, and the film formation may be performed under these conditions.

According to the tenth embodiment, since the above film deposition condition (film deposition temperature condition of lower than 480° C.) is applied, the amount of polysilazane film 4b formed in the element isolation trench 3 can be reduced in comparison with that of the former embodiment and the effect of reducing the tensile stress can be further attained.

(Modification)

This invention is not limited to the ninth and tenth embodiments and, for example, the following modification or expansion can be made. The gate electrodes PG in the peripheral circuit region P may be applied to either high-operation voltage transistor series or low-operation voltage transistor series. This invention is applied to a NAND flash memory 1, but may be applied to a NOR flash memory or other nonvolatile semiconductor memory device. Further, this invention can be applied to a structure in which a plurality of memory cell gate electrodes MG in the memory cell region M that lie near the dummy region RD are formed as a dummy electrode DG.

As described above, according to one aspect of this invention, a semiconductor device and the manufacturing method thereof that can prevent occurrence of crystalline defects caused by dislocation can be attained.

### Eleventh Embodiment

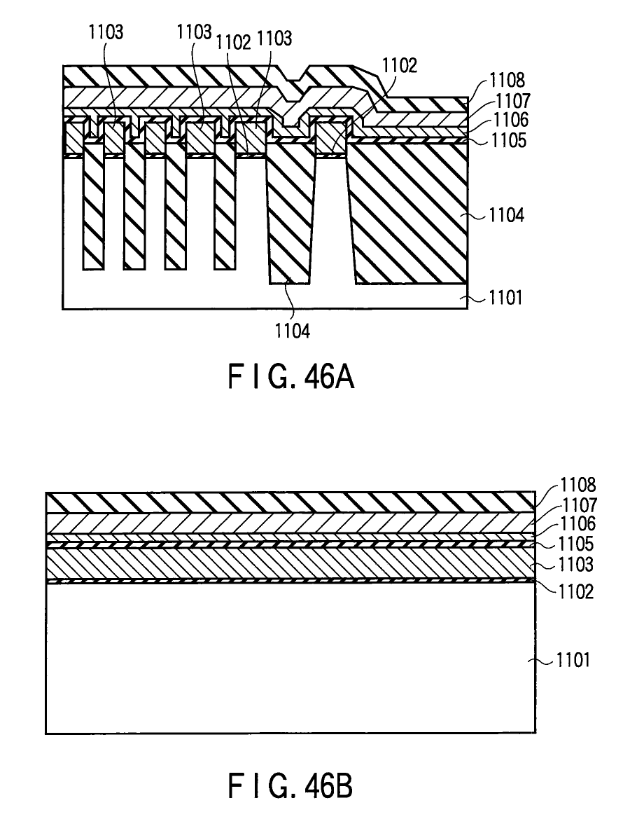

A flash memory and a manufacturing method thereof according to an eleventh embodiment of this invention are explained with reference to FIGS. 46A, 46B to FIGS. 52A, 52B. FIGS. 46A to 52A are cross-sectional views taken in the word line direction and FIGS. 46B to 52B are cross-sectional views taken in the bit line direction. This embodiment is an example in which post-oxidation is performed after an O₃-TEOS film having high underlying material selectivity is filled in each portion between adjacent word lines and then an O₃-TEOS film having no underlying material selectivity is filled in remaining space portions.

According to this system, each space between the word lines is filled without causing any seam in a form in which the bottom is raised from the substrate silicon portion. With this structure, the seam portion of the O₃-TEOS is etched in a wet step after the portion between the word lines is filled and a silicon nitride film can be suppressed from entering the space, which would otherwise increase the parasitic capacitance.

First, as shown in FIGS. 46A and 46B, a silicon thermal oxynitride film 1102 with a thickness of 8 nm used as gate dielectric films, a P-doped polysilicon film 1103 with a thickness of 60 nm used as floating gates (charge storage layers) and a silicon nitride film (not shown) with a thickness of 60 nm used as a CMP stopper are stacked on a semiconductor substrate (silicon substrate) 1101. Then, the silicon nitride film, P-doped polysilicon film 1103, silicon thermal oxynitride film 1102 and semiconductor substrate 1101 are sequentially patterned by a known lithography technique and etching technique to form isolation trenches with an etching depth of approximately 220 nm for formation of trench isolation (for example, shallow trench isolation: STI) portions. Next, the isolation trenches are filled with a dielectric film by using a known dielectric film forming technique and the dielectric film is left behind only in the isolation trenches by the CMP technique with the silicon nitride film used as a stopper to form STI portions 1104.

After this, the height of the STI portion 1104 is adjusted by reactive ion etching or the like and then an ONO film 1105 used as an inter-polysilicon gate dielectric film (IPD) is formed. Next, a P-doped polysilicon film 1106 used as control gate electrodes (=word lines) is formed and openings are formed in portions of the ONO film 1105 that lie on the P-doped polysilicon film 1103 other than the cell portion by a known lithography technique and etching technique. Further, a P-doped polysilicon film 1107 used as control gate electrodes (=word lines) and a silicon nitride film 1108 used as a hard mask are formed.

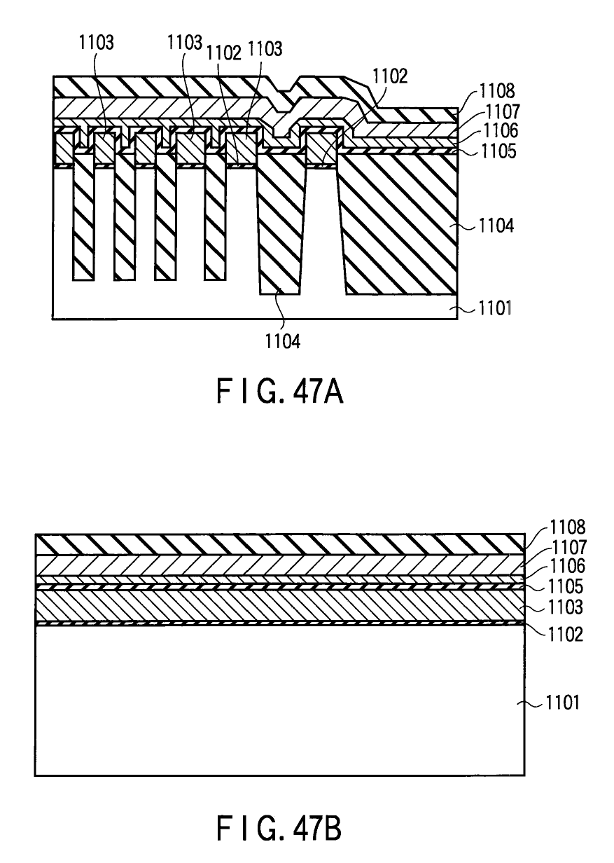

Next, as shown in FIGS. 47A and 47B, the silicon nitride film 1108, P-doped polysilicon film 1107, ONO film 1105 and P-doped polysilicon film 1103 are sequentially patterned by a well known lithography technique and RIE technique to form control gates and floating gates. At this time, the silicon thermal oxynitride film 1102 is also etched to expose the surface portions of the semiconductor substrate 1101 that lie between the word lines.

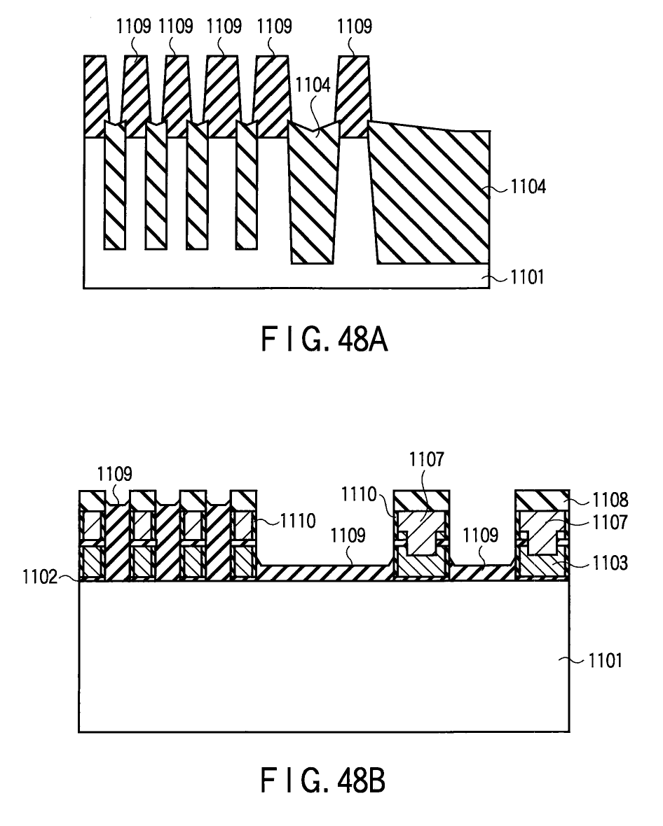

Then, as shown in FIGS. 48A and 48B, an O₃-TEOS film 1109 having high underlying material selectivity is formed to a thickness of approximately 40 nm. In this case, TEOS (tetraethoxysilane) and O₃ are used as a source gas and film deposition is performed at 450° C. or lower to enhance the underlying material selectivity. At this film deposition temperature, the film deposition rate of the O₃-TEOS film is the highest on Si and gradually becomes lower on the films in the order of the silicon nitride film, silicon thermal oxynitride film and doped polysilicon film (an O₃-TEOS film is difficult to be deposited since the surface of the doped polysilicon film is immediately oxidized by O₃ at the very early stage of the O₃-TEOS film deposition).

Therefore, since the O₃-TEOS film is formed in a bottom-up form from the silicon substrate in the state in which the surface portions of the silicon substrate 1101 that lie between the respective word lines are exposed as in this embodiment, portions on the silicon substrate 1101 that lie between the word lines are filled without causing any seams. Particularly, the bottom-up formation rate is high in the cell portion in which the spaces are narrow and the bottom-up formation process is not substantially performed in the peripheral circuit portion in which the spaces are wide. However, incase of the STI portions even between the word lines, almost no deposition occurs since the film deposition rate of the O₃-TEOS film having high underlying material selectivity.

Next, a post-oxidation process using a hydrogen/oxygen mixed gas is performed at a high temperatures to oxidize the side surfaces of the word lines over the O₃-TEOS film 1109 having high underlying material selectivity and form a silicon thermal oxide film 1110. As a result, gate electrode patterning damage is eliminated and the end portions of the floating gates are oxidized and rounded to reduce the electric field concentration.

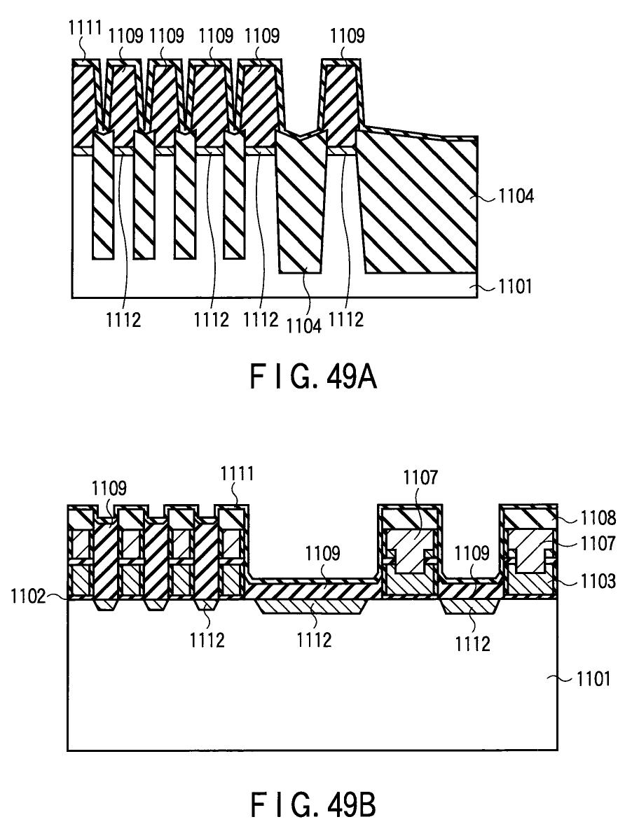

Subsequently, as shown in FIGS. 49A and 49B, an O₃-TEOS film 1111 having no underlying material dependence is formed to a thickness of approximately 20 nm on the exposed surfaces of the O₃-TEOS films 1109 and STI portions 1104. Then, ion-implantation is performed with the O₃-TEOS film 1111 used as the sidewall spacers of the gate electrodes to form diffusion layers 1112 of the peripheral circuit portion. In this embodiment, the O₃-TEOS film is used, but a high temperature oxide (HTO) film formed by an LPCVD method using SiH₄/N₂O or SiH₂Cl₂/N₂O or a TEOS film formed by the LPCVD method can be used instead of the above film.

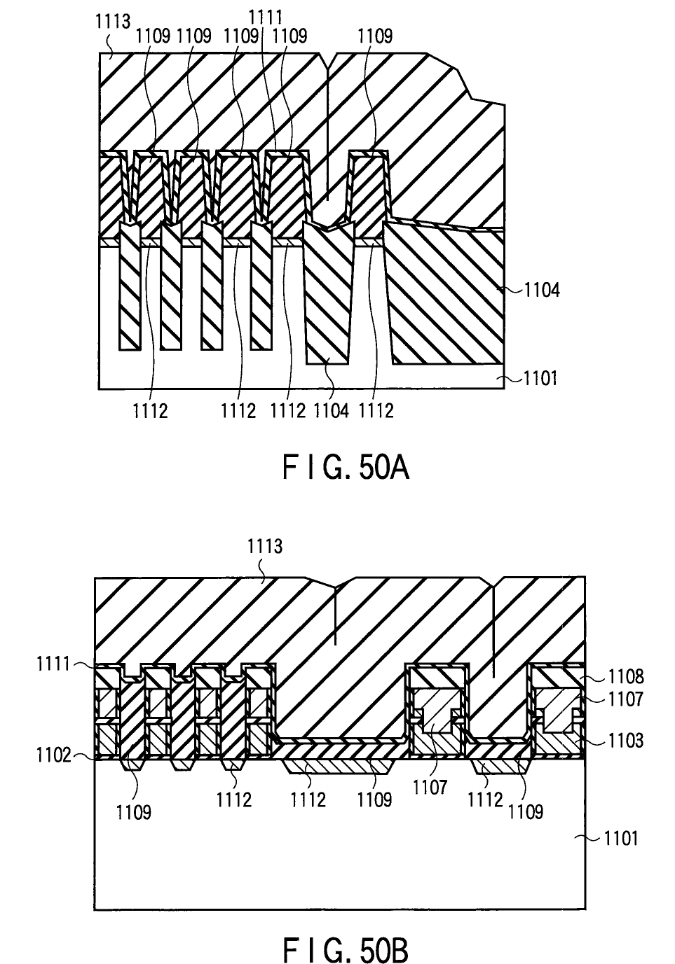

Next, an O₃-TEOS film 1113 having no underlying material dependence is formed to completely fill the spaces between the word lines that are not filled with the O₃-TEOS films 1109 and O₃-TEOS film 1111. At this time, since the upper portions of the STI portions between the respective word lines are surrounded by and filled with the above film, seams are left only in the central portions thereof and thus the structure shown in FIGS. 50A and SOB is attained.

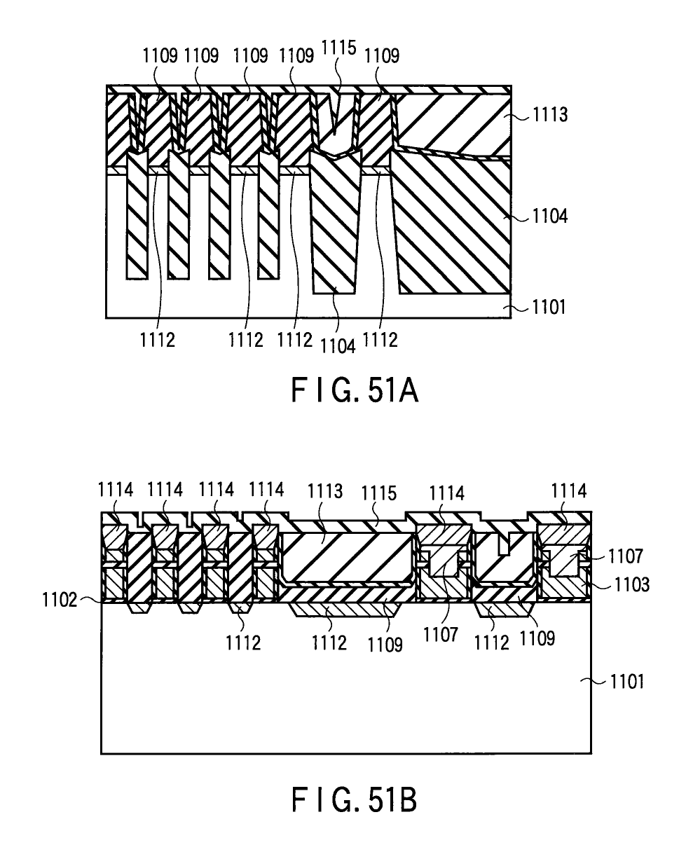

Then, as shown in FIGS. 51A and 51B, the O₃-TEOS films 1109, 1111, 1113 are planarized by the CMP method, the silicon nitride film 1108 and O₃-TEOS films 1111, 1113 are etched back by reactive ion etching to expose the upper portions of the P-doped polysilicon films 1107. Next, a cobalt film is formed by sputtering after the oxide films on the surfaces of the P-doped polysilicon films 1107 are removed by use of an appropriate etching technique and then a cobalt silicide film 1114 is formed by silicidation. Subsequently, a silicon nitride film 1115 is formed by an LPCVD method in order to protect the cobalt silicide film 1114.

In the method of this embodiment, since the locations of formation of the seams caused by the presence of the filling dielectric films between the word lines are only the central portions of the STI portions, a phenomenon that silicon nitride films penetrate portions (between adjacent word lines) in which the parasitic capacitance becomes a problem will not occur. Therefore, a preferable write characteristic of the device can be securely attained.

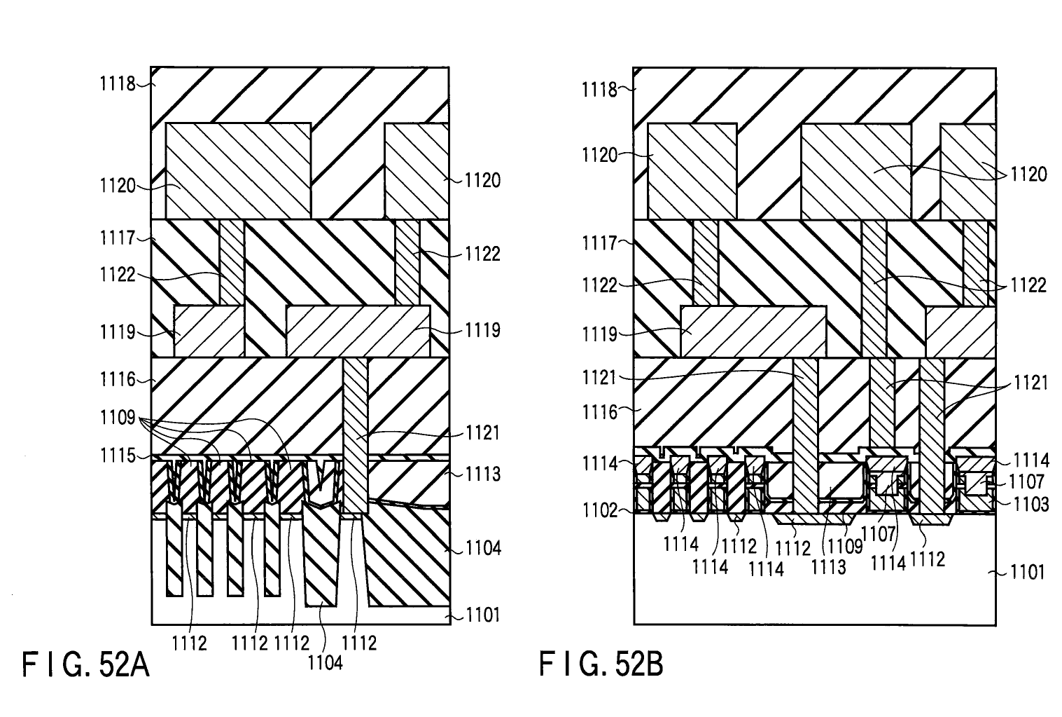

In the succeeding process, inter-layer dielectric films (ILD) 1116, 1117, 1118 are formed and interconnections 1119, 1120 and contact plugs 1121, 1122 are formed, but the detailed explanation thereof is abbreviated and only the final structure of a device is shown (FIGS. 52A, 52B).

In this embodiment, since an O₃-TEOS film having high underlying material dependence and the O₃-TEOS film having no underlying material dependence are used in combination for filling, particularly, the portions between the adjacent word lines are filled without causing any seam, and penetration of silicon nitrogen films can be suppressed, then the flash memory can be further downsized without degrading the write characteristic.

### Twelfth Embodiment

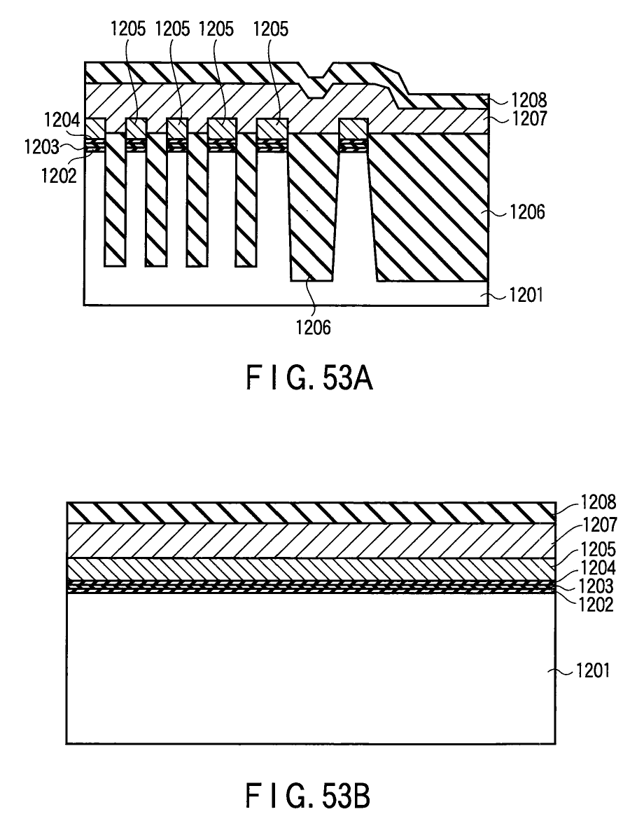

A flash memory and a manufacturing method thereof according to the twelfth embodiment of this invention are explained with reference to FIGS. 53A, 53B to 59A, 59B. FIGS. 53A to 59A are cross-sectional views taken in the word line direction and FIGS. 53B to 59B are cross-sectional views taken along the bit line direction. Unlike the eleventh embodiment, this embodiment is an example applied to a MONOS flash memory.

As shown in FIGS. 53A and 53B, a silicon thermal oxynitride film 1202 with a thickness of 4 nm used as gate dielectric films, a silicon nitride film 1203 with a thickness of 10 nm used as charge trap films (charge storage layers), an alumina film 1204 with a thickness of 10 nm used as charge block films, a P-doped polysilicon film 1205 with a thickness of 30 nm used as gate electrodes and a silicon nitride film (not shown) with a thickness of 60 nm used as a CMP stopper are stacked on a semiconductor substrate (silicon substrate) 1201. Then, the silicon nitride film, P-doped polysilicon film 1205, alumina film 1204, silicon nitride film 1203, silicon thermal oxynitride film 1202 and semiconductor substrate 1201 are sequentially patterned by using a known lithography technique and etching technique to form isolation trenches with an etching depth of approximately 220 nm used as STI portions.

Next, the isolation trenches are filled with a dielectric film by use of a known dielectric film forming technique and the dielectric film is left only in the isolation trenches by use of the CMP technique with the silicon nitride film used as a stopper to form STI portions 1206. Subsequently, the height of the STI portion 1206 is adjusted by reactive ion etching or the like and then a P-doped polysilicon film 1207 used as control gates (=word lines) and a silicon nitride film 1208 used as a hard mask are formed.

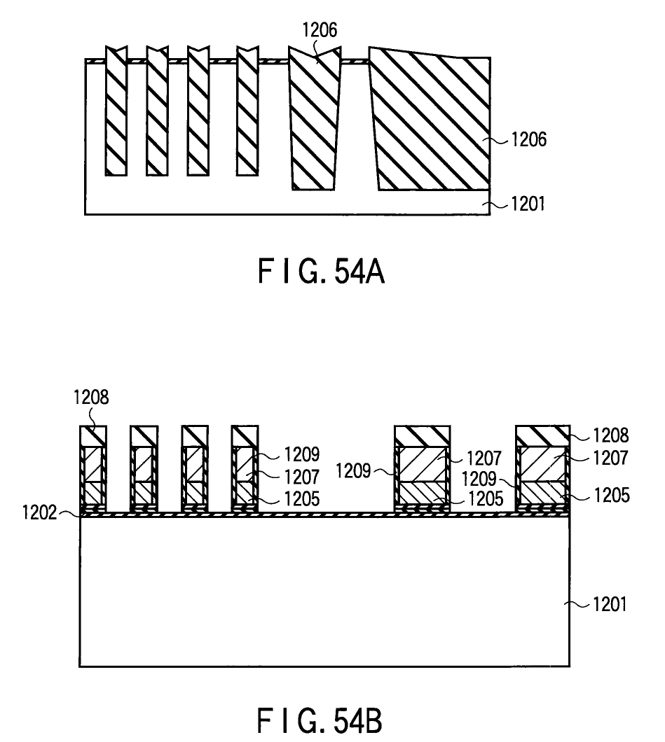

Next, as shown in FIGS. 54A and 54B, the silicon nitride film 1208, P-doped polysilicon film 1207, P-doped polysilicon film 1205, alumina film 1204 and silicon nitride film 1203 are sequentially patterned by a known lithography technique and RIE technique to form word lines. Then, the side surfaces of the P-doped polysilicon films 1207, 1205 are oxidized by plasma oxidation to form silicon thermal oxide films 1209 and post-oxidation for rounding and oxidizing, particularly, the lower end portions of the P-doped polysilicon films 1205 is performed.

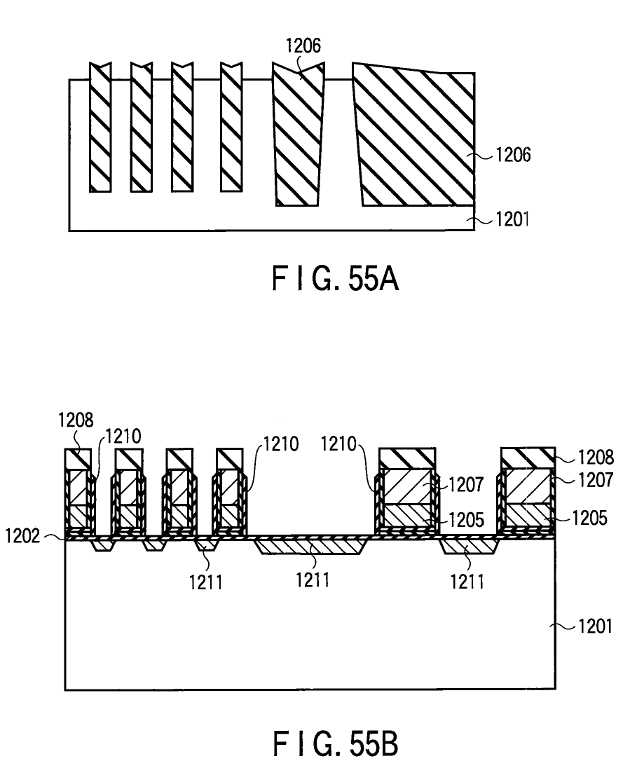

Next, an HTO film 1210 is deposited to a thickness of 10 nm on the entire surface of the substrate and ion-implantation is performed by using the HTO film and the silicon thermal oxide films 1209 formed by post-oxidation as sidewall spacers of the gate electrodes to form diffusion layers 1211 in the peripheral circuit portion. Then, a sidewall patterning process is performed by a reactive ion etching technique to leave the films only on the sidewalls of the word lines. At this time, the silicon thermal oxynitride film 1202 is partly removed to expose surface portions of the semiconductor substrate 1201 that lie between the word lines on the active area. Thus, the semiconductor structure as shown in FIGS. 55A and 55B is attained.

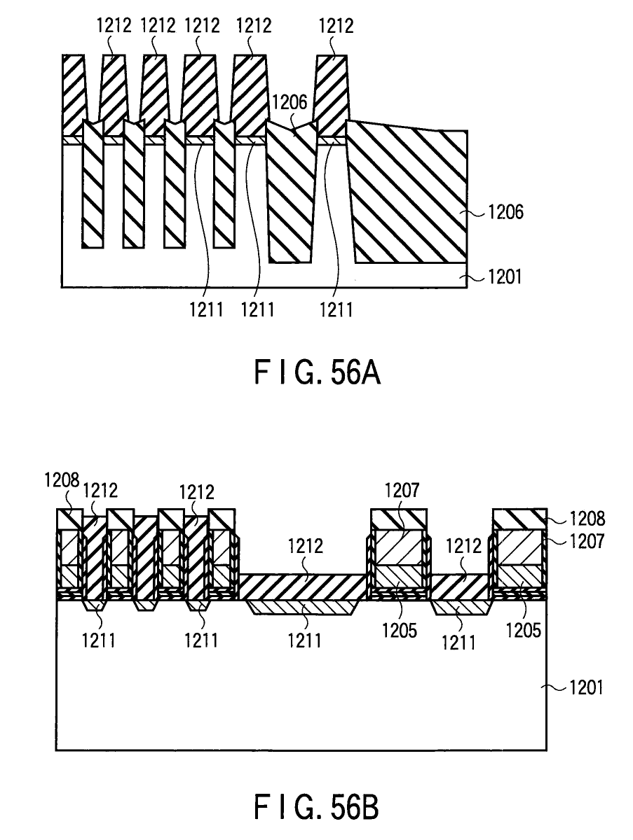

Next, as shown in FIGS. 56A and 56B, O₃-TEOS films 1212 having high underlying material selectivity are deposited. At the film deposition time, tetraehoxysilane (TEOS) and O₃ are used as a reactive gas and the film formation process is performed at 410° C. or lower in order to further enhance the underlying material selectivity. At this film deposition temperature, the film deposition rate of the O₃-TEOS film is the highest on Si and gradually becomes lower on the films in the order of the silicon nitride film, alumina film, silicon thermal oxide film and doped polysilicon film (an O₃-TEOS film is difficult to be formed since the surface of the doped polysilicon film is immediately oxidized by O₃ during the O₃-TEOS film deposition).

Therefore, since each O₃-TEOS film 1212 is formed in a bottom-up form from the silicon substrate 1201 in the state in which the surface portions of the semiconductor substrate 1201 that lie between the word lines are exposed as in this embodiment, portions on the silicon substrate 1201 that lie between the word lines are filled without causing any seam. However, since the film deposition rate of the O₃-TEOS film having high underlying material selectivity on the STI portion 1206 between the word lines is low, almost no deposition occurs.

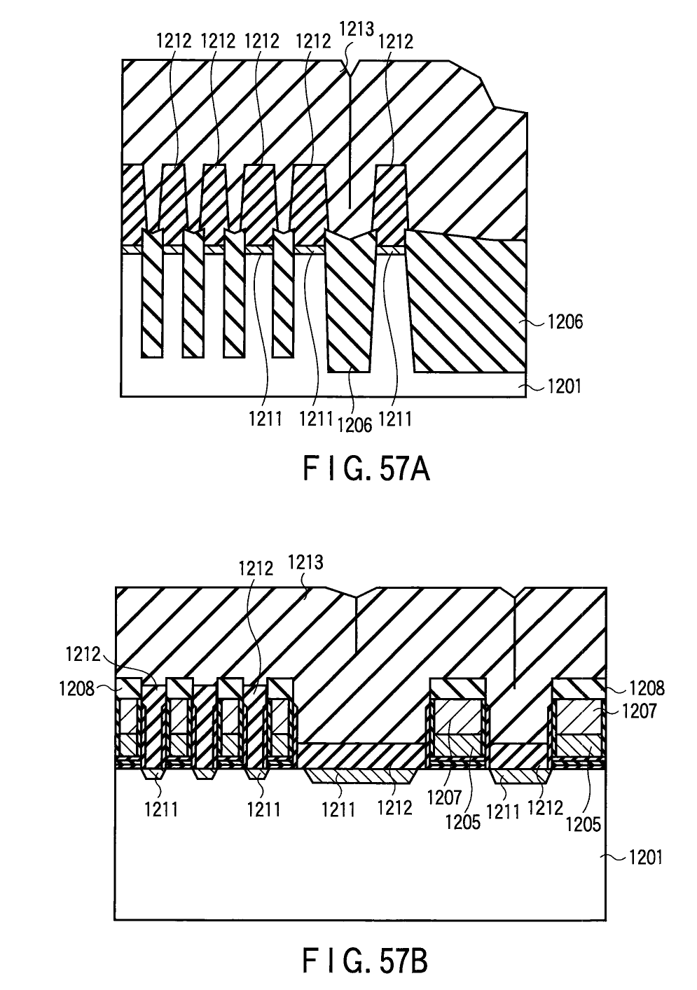

Next, spaces between the word lines that are not filled with the O₃-TEOS films 1212 are completely filled with an O₃-TEOS film 1213 having no underlying material dependence. At this time, since the upper portions of the STI portions between the word lines are surrounded by and filled with the above film, seams are left only in the central portions thereof and thus the structure shown in FIGS. 57A and 57B is attained.

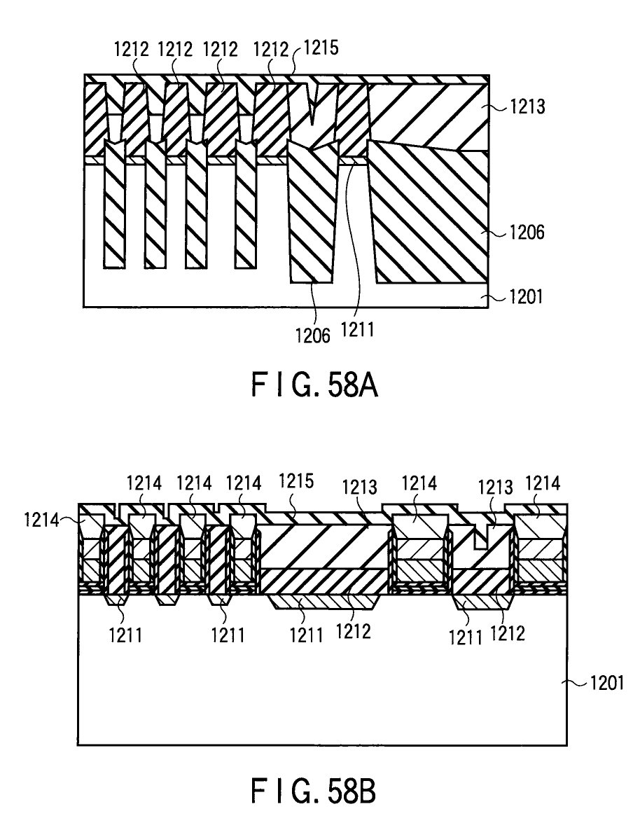

Then, as shown in FIGS. 58A and 58B, the O₃-TEOS films 1213, 1212 are planarized by the CMP method, the silicon nitride film 1209 and O₃-TEOS films 1213, 1212 are etched back by reactive ion etching to expose the upper portions of the P-doped polysilicon films 1208. Next, a nickel-platinum alloy film is sputtered, after oxide films on the surfaces of the P-doped polysilicon films 1208 are removed, by use of an adequate etching technique and then a nickel-platinum silicide film 1214 is formed by silicidation. After this, a silicon nitride film 1215 is formed by a plasma-CVD method in order to protect the nickel-platinum silicide film 1214.

In the method of this embodiment, since the positions of the seams caused by the presence of the filling dielectric films between the word lines are only the central portions of the STI portions, a phenomenon that silicon nitride films penetrate portions (between adjacent word lines) in which the parasitic capacitance becomes a problem will not occur. Therefore, a device with a preferable write characteristic can be securely attained.

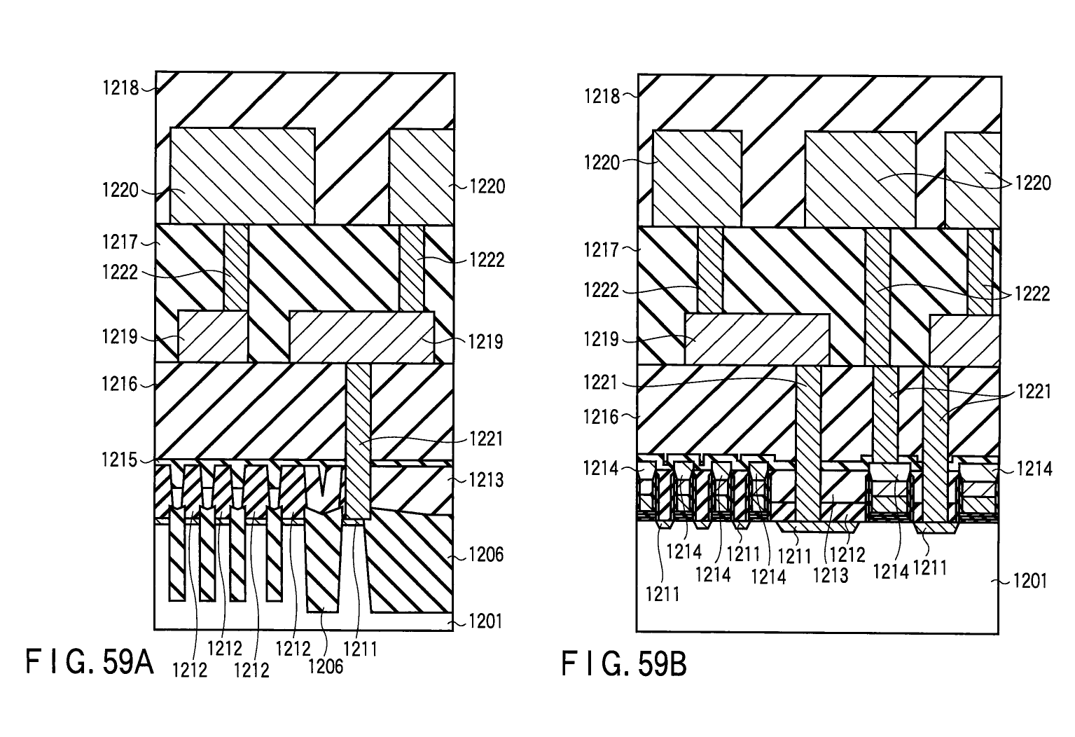

In the succeeding process, inter-layer dielectric films (ILD) 1216, 1217, 1218 are formed and interconnections 1219, 1220 and contact plugs 1221, 1222 are formed, but the detailed explanation thereof is omitted and only the final structure of a device is shown (FIGS. 59A, 59B).

In this embodiment, since the O₃-TEOS film having high underlying material dependence and the O₃-TEOS film having no underlying material dependence are used in combination for filling, particularly, the portions between the adjacent word lines are filled without causing any seam and the penetration of silicon nitrogen films can be suppressed, then the flash memory can be further downsized without degrading the write characteristic.

This invention is explained by taking the eleventh and twelfth embodiments as examples, but this invention is not limited to the combinations shown in the above embodiments and the same effect can be attained by adequately combining the processes described in the above embodiments.

As described above, the manufacturing method of the flash memory according to the eleventh embodiment of this invention includes stacking a gate dielectric film used to form memory cells of the flash memory and the first conductive film used as floating gates on the semiconductor substrate, forming isolation trenches used as trench isolation (for example, STI: shallow trench isolation) portions by processing the stacked first conductive film and gate dielectric film and the semiconductor substrate by reactive ion etching, forming STI portions by filling the isolation trenches with the first dielectric films, forming word lines and floating gates by forming the second dielectric film used as inter-polysilicon gate dielectric films and the second conductive film used as control gates on the substrate and patterning the second conductive film, the second dielectric film and first conductive film by reactive ion etching, post-oxidation of the side surfaces of the word lines or floating gates exposed by at least word line patterning, and exposing surface portions of the semiconductor substrate that lie on an active area between the respective word lines. It further includes filling an O₃-TEOS film exhibiting underlying material selectivity during deposition as the third dielectric film used to fill portions between the word lines without causing any seam, and completely filling portions between the word lines by filling the fourth dielectric film on the O₃-TEOS film exhibiting underlying material selectivity.

Further, as a preferable embodiment of this invention, the following examples are provided.

(a) The exposure of the surface portions of the semiconductor substrate that lie on the active area between the word lines refers to exposing the surface portions of the semiconductor substrate by processing the gate electrode film when the word lines are patterned by reactive ion etching.

(b) The post-oxidation refers to oxidizing the side surfaces of the word lines or floating gates through the O₃-TEOS film after the O₃-TEOS film exhibiting underlying material selectivity during deposition is filled into the portions between the word lines without causing any seam.

(c) The exposure of the surface portions of the semiconductor substrate that lie on the active area between the word lines refers to removing a silicon oxide film on the surface of the semiconductor substrate on the active area by reactive ion etching after the word lines patterning and post-oxidation.

In the flash memory according to the twelfth embodiment of this invention, the portions on the active area between the adjacent word lines are filled with the O₃-TEOS film without causing any seam and the STI portions between the adjacent word lines are surrounded by and filled with a dielectric film.

According to the above manufacturing method and structure, the following effects are obtained.

(1) Since an O₃-TEOS film can be deposited without causing any seams or voids in portions between the adjacent word lines by forming the O₃-TEOS film under a condition having high underlying material selectivity on the isolation trenches formed to expose silicon on the substrate portion, it can be prevented that the portions between the adjacent word lines are eroded during the wet process of a later step. Further, a problem that silicon nitride films penetrate the erosion to increase the parasitic capacitances between the adjacent word lines can be suppressed.

(2) By utilizing the condition having high underlying material selectivity, the O₃-TEOS film can be grown in a bottom-up form from substrate silicon and occurrence of seams or voids in the O₃-TEOS film can be suppressed. Therefore, it becomes unnecessary to perform oxidation in the steam atmosphere normally used for eliminating seams and densification of the O₃-TEOS film, and the densification of the O₃-TEOS film can be performed with annealing in an atmosphere of an inert gas such as nitrogen. As a result, a bad influence to the characteristic of a flash memory due to substrate oxidation during the steam atmosphere annealing of the conventional densification of the O₃-TEOS film can be prevented.

(3) It is difficult to form an O₃-TEOS film thick under the condition of high underlying material selectivity, but the process time for forming an O₃-TEOS film under the condition of high underlying material selectivity can be shortened by utilizing the same in combination with the second dielectric film.

Further, according to the manufacturing method (a), since the shape of the isolation trenches can be formed such that the O₃-TEOS film having high underlying material selectivity can be easily filled, an O₃-TEOS film can be formed without causing any seams or voids.

According to the manufacturing method (b), damage caused in the RIE process for patterning the gate electrodes can be eliminated by performing a post-oxidation process, which is a general damage eliminating method, while an O₃-TEOS film having high underlying material selectivity is used.

According to the manufacturing method (c), damage caused in the RIE process for patterning the gate electrodes can be eliminated by performing a post-oxidation process, which is a general damage eliminating method, and portions between the adjacent word lines can be filled without causing any seams or voids by utilizing an O₃-TEOS film having high underlying material selectivity.

As described above, according to the eleventh and twelfth embodiments, a flash memory with a preferable element characteristic and a manufacturing method thereof can be provided by suppressing the interference between the neighboring cells with filling the portions between the adjacent word lines without causing any seam by using the O₃-TEOS film under the low temperature deposition condition adjusted for the high underlying material selectivity. Thus, since extremely narrow word lines can be attained, the performance/bit density thereof can be enhanced by further downsizing of the flash memory.

As described above, according to one aspect of this invention, a flash memory in which portions between the adjacent word lines are filled without causing any seam and interference between the cells is suppressed and that has a preferable element characteristic and a manufacturing method thereof can be attained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A manufacturing method of a semiconductor device comprising:
forming a stacked film configuring a semiconductor device on a semiconductor substrate,
patterning the stacked film by reactive ion etching to form an isolation trench that isolates elements and expose a surface of the semiconductor substrate at least a bottom portion of the isolation trench,
filling an O₃-TEOS series film exhibiting underlying material selectivity as a first filling dielectric film in the isolation trench to have a thick film thickness on the bottom portion of the isolation trench, and
filling the isolation trench with a second filling dielectric film to form an element-element isolation region.

2. The manufacturing method of the semiconductor device according to claim 1, wherein the second filling dielectric film includes one of an O₃-TEOS series film having a smaller underlying material selectivity than the O₃-TEOS series film during the film deposition, a silicon oxide film deposited by a high-density plasma-CVD method and an SOG film.

3. The manufacturing method of the semiconductor device according to claim 1, further comprising forming one of a polysilicon film, amorphous silicon film and silicon germanium film acting as a stopper in a chemical mechanical polishing process as part of the stacked film configuring the semiconductor device.

4. The manufacturing method of the semiconductor device according to claim 1, further comprising oxidizing an internal surface of the isolation trench over the first filling dielectric film after forming the O₃-TEOS series film that is the first filling dielectric film and before filling the isolation trench with the second filling dielectric film.

5. The manufacturing method of the semiconductor device according to claim 1, wherein the forming the O₃-TEOS series film is performed while pure water is being introduced into a process chamber.

6. The manufacturing method of the semiconductor device according to claim 1, in which the stacked film includes a third dielectric film used as gate dielectric films of memory cells and a first conductive film used as charge storage layers and which further comprises forming a fourth dielectric film on the first conductive film, forming a second conductive film on the third dielectric film, patterning the second conductive film and fourth dielectric film to form word lines and charge storage layers that partially act as the control gates, exposing a surface of the semiconductor substrate on an active area in portions between the adjacent word lines, filling an O₃-TEOS film exhibiting underlying material selectivity during the film deposition as the first dielectric film on the exposed surface of the semiconductor substrate in the portions between the adjacent word lines, and filling the second dielectric film on the first dielectric film to fill the portions between the adjacent word lines.

7. The manufacturing method of the semiconductor device according to claim 6, wherein the exposing the surface of the semiconductor substrate is exposing the surface of the semiconductor substrate by further advancing the etching to remove the third dielectric film when the second conductive film, fourth dielectric film and first conductive film are patterned by the etching process.

8. The manufacturing method of the semiconductor device according to claim 6, further comprising oxidizing side surfaces of the word lines and charge storage layers through the fourth dielectric film after filling the first dielectric film into the portions between the adjacent word lines.

9. The manufacturing method of the semiconductor device according to claim 6, wherein the exposing the surface of the semiconductor substrate is performed by patterning the second conductive film, fourth dielectric film and first conductive film by the etching process and eliminating a silicon oxide film formed on the surface of the semiconductor substrate on the active area by further performing the etching process after post oxidation.

10. The manufacturing method of the semiconductor device according to claim 6, wherein the forming the O₃-TEOS series film is performed while pure water is being introduced into a process chamber.

11. A semiconductor device comprising:
an active area formed on a semiconductor substrate, and
a shallow trench isolation portion having an isolation trench formed to separate the active area from an adjacent active area and a dielectric film filled in the isolation trench,
wherein the dielectric film filled in the isolation trench is a stacked film having a first dielectric film formed of an O₃-TEOS series film filled to have a thick film thickness on a bottom portion of the isolation trench and a second dielectric film formed on the first dielectric film.

12. The semiconductor device according to claim 11, wherein the active area includes a memory cell portion having elements isolated by a first isolation trench and a peripheral circuit portion having elements isolated by a second isolation trench having wider width than the first isolation trench, and an O₃-TEOS series film that is the first dielectric film is filled to have a thicker film thickness on corners of the bottom portion of the second isolation trench.

13. The semiconductor device according to claim 11, wherein the first isolation trench is substantially filled with an O₃-TEOS series film that is the first dielectric film.

14. The semiconductor device according to claim 11, wherein an O₃-TEOS series film that is the second dielectric film filled in the second isolation trench is formed to have not higher than 1:1.5 in a film thickness ratio of film portions formed on sidewalls and bottom portion of the element isolation trench and have a film thickness of not smaller than 50 nm on the bottom portion of the element isolation trench.

15. The semiconductor device according to claim 11, wherein the second dielectric film includes one of an O₃-TEOS series film, a silicon oxide film formed by a high-density plasma-CVD method and an SOG film.

16. The semiconductor device according to claim 15, wherein the SOG film is a polysilazane film.

17. A semiconductor device comprising:
memory cells each having a gate dielectric film, charge storage layer, inter-polysilicon gate dielectric film and control gate stacked on a semiconductor substrate,
an element isolation region of a trench isolation structure formed on the semiconductor substrate,
the first dielectric films formed of O₃-TEOS series films filled in portions on an active area between adjacent word lines without causing any seam,
the second dielectric films filled on the first dielectric films in the portions between adjacent word lines, and
the third dielectric films filled to surround upper portions of the element isolation region in the portions between adjacent word lines.

18. The semiconductor device according to claim 17, wherein side surfaces of the charge storage layers and word lines are oxidized.

19. The semiconductor device according to claim 17, wherein the second dielectric film includes one of an O₃-TEOS series film, a silicon oxide film formed by a high-density plasma-CVD method and an SOG film.

20. The semiconductor device according to claim 19, wherein the SOG film is a polysilazane film.
